(19) United States
(12) Patent Application Publication
(10) Pub. No.: US 2012/0078680 A1
(43) Pub. Date: Mar. 29, 2012

(54) Electrical Engineering And Capacity Management System And Method

(76) Inventor: Brian Tharp, Folsom, CA (US)

(21) Appl. No.: 13/241,143

(22) Filed: Sep. 22, 2011

Related U.S. Application Data
(60) Provisional application No. 61/385,442, filed on Sep. 22, 2010.

(51) Int. Cl. G06Q 10/00; G01R 19/00; H01R 43/00

(52) U.S. Cl. 705/7.28; 705/1.1; 29/825; 324/66

(57) ABSTRACT

An electrical system and method are provided that has a software system that provides the electrical engineer or designer the capability to design and document the complete electrical infrastructure within a facility and be made available to a facility operations group to monitor and manage capacity, consumption and risk. Furthermore it provides information technology personnel or project/change management system the ability to understand the capabilities of the electrical system as well as include financial metrics for finance as well as all parties to understand the cost of the facility from an operations, capital and power consumption perspective.

### PRIORITY CLAIM/RELATED APPLICATION

This application claims the benefit, under 35 USC 119(e) and 120, to U.S. Provisional Patent Application Ser. No. 61/385,442, filed on Sep. 22, 2010 titled “Electrical Engineering And Capacity Management System And Method”, the entirety of which is incorporated herein by reference.

### FIELD

The disclosure relates to current monitoring based systems of electrical power distribution systems and providing engineering and management processes to electrical power distribution systems. In more detail, the disclosure relates to multiple branch circuits from load centers, and the entirety of the facility electrical system connected to a multi-enterprise software database solution that provides for the engineering and electrical design of a facility as well as tracking and design of individual circuits as well as the ability to manage and report on capacity consumption and risk at each hierarchal level of the electrical distribution system.

### BACKGROUND

Information Technology usage has exploded in the past 20 years since the advent of the PC Server platform. Governments, corporations and businesses of every size have built data centers to protect their IT equipment. The data center supports and protects the IT infrastructure to assure no disruptions occur to business applications running on the IT equipment served by the data center. The size and complexity of data centers have grown to a point that existing methods of building design and engineering no longer support the rapid change within the electrical distribution system that exists in this highly dynamic environment.

The current art for building design and engineering uses computer aided drafting applications to create the building design and details all elements of the building construction. This approach also is used to document complex electrical systems; this type of drawing is typically referred to in the trade as a “single-line or one-line” as shown in FIG. 15 & FIG. 16. An electrical system is thus documented visually in a drawing created by a draftsperson or engineer. Furthermore, schedules of connections are also depicted in tables with rows, and columns to group the data in an orderly fashion as shown in FIG. 8.

The engineering of branch circuits from load center panels, such as shown in FIG. 9, is done via a CAD drawing and schedules of tables as shown in FIG. 8 during the initial construction of a facility or data center. Typically a computer spread sheet application like Microsoft Excel is used. The table in FIG. 8 is used to keep track of changes once the building is constructed. The load center documentation is typically referred to as a “panel schedule”. Today engineering documentation of circuits is performed in spreadsheet applications and a paper copy is printed out to document the contents of a load center or breaker panel. Requests for new circuits are originated by clients or requestors of data center support and are submitted to the engineer or facility operator via a computer or email system. These requests are typically documented in another format of a spreadsheet application and submitted to the engineer. Therefore, all documentation about the facility is a collection of computer files, drawings or spreadsheets that must each be independently examined as if they were paper based.

All of an engineer's panel indexes have typically been based off of connected load in the past. Connected load is defined as the load provided to the engineer by the end user requesting the circuits. It is common practice in the industry to look at the name plate rating of a piece of electrical equipment and use that load value or some percentage thereof to provide the engineer guidance on how much load the engineer should reserve on a load center. This works fine in static environments with static loads such as motors or lights but creates risk and waste in a dynamic environment such as a data center or facility where many different hardware components will draw on a specific circuit. Furthermore, the hardware loads are refreshed from time to time. Existing hardware is replaced by new hardware presenting a new load dynamic on the circuit. This type of ebb and flow of IT hardware, for instance, takes place without the engineer's knowledge well after a circuit is deployed. These dynamics necessitate monitoring.

The engineer must also update the fundamental components of the electrical distribution (e.g. distribution panels, UPS systems, generators) system from time to time as growth of the data center or component failure occurs.

One other component of a typical data center design that creates risk is the dual distribution within this type of facility to assure uptime of the equipment being serviced by the dual design. Due to this dual design, neither leg of the dual distribution system may have more than a 50% load, for example. If one leg fails, all the power consumption from the failed leg will now occur on our remaining leg and if both legs are 50% or greater it's obvious that the remaining leg will fail thus dropping the entire load. Either leg having a load greater than 50% is defined as a Latent Risk. Latent risk resides in the environment unknown to the user or the load until a single failure occurs and then a secondary failure occurs because the legs of the dual distribution system were over 50% used.

Due to technology updates of IT equipment, there is a great deal of change in the supply of power cooling and floor space. The increasing power and space density of IT equipment has also exacerbated this change. In the mid 90's, a typical IT server had a single 200 W power supply and that server had a volume of 4320 cubic inches and the typical data center had a power density below 25 W/Sq.Ft. Today IT equipment comes with multiple power supplies having ratings as high as 3000 W and the typical IT device has a volume of 1200 cubic inches.

Due to the change in demand, data center owners are seeking out solutions to help them monitor or manage their electrical systems. There are several choices for owners that are building out new infrastructure but one choice for owners with existing infrastructure. Data centers are designed to be up 24×7×365 so their owners will not accept solutions that require the shut-off of critical equipment. Therefore the only solution they currently have available is a split-core branch circuit monitoring system. Furthermore, data center owners typically have very short work windows in which to perform work on critical infrastructure equipment such as the power supply system. In some environments, this could be as short as 6 hours/week made available for maintenance.

Facilities faced with many capacity, consumption and risk mitigation problems have several choices to add intelligence for new build-outs. Some find it desirable to add smart power strips at the cabinet level. However this does not solve the problem of understanding what's happening in the existing infrastructure. The only way to retrofit an intelligence device into the existing infrastructure to understand the system is to use a split-core current transformer (CT) or Rogowski coil on an existing conductor within the load center panel, such as shown in FIG. 9, that is distributing loads out to electrical consumers. Split-core or coil solutions are necessitated in a data center, for instance, due to the fact that data center operators will not allow IT loads to be shut down for maintenance. The majority of business IT loads are “on” and in demand 24 hours a day. A split core or coil solution provides another benefit for new equipment installs as well. If a split core or coil design is used and implemented, it can be removed and replaced in the field without disruption to the critical loads thus allowing for repair of faulty units.

A fault in existing solid core designs is that when a CT goes bad the customer has to live without data on that circuit. As a result, a split core or coil Branch Circuit Monitoring solution is the typical optimal way to solve this business need. However, conventional system solutions that can typically cost many more times to install existing branch circuit monitoring systems than to purchase the hardware. These installation costs are driven by two components of installation, the pipe and wire to connect all the branch circuit monitoring systems to a central processing system as shown in FIG. 6 and the individual CT's or coils that must be connected to each conductor to monitor consumption. One attempt to solve this time factor was to present a string of current sensors like a string of holiday tree lights to connect to consecutive conductors but in a high-density installation typically 21 to 42 conductors to a panel this is still unwieldy.

Branch circuit monitoring systems are deployed to address several critical issues for the data center operator such as reducing risk due to over-subscription and providing power consumption information. Risk can be avoided by simply analyzing the current flow through the individual CTs and providing an alarm when a pre-subscribed threshold is met. Power (kW, Power Factor) requires additional analysis but this is well known.

Installation of branch circuit monitoring systems that can support the data center owners need for non-disruption of loads come in several flavors. Typically taking the form of an iron core split CT connected by 2 wires to a data collection board that is comprised of a printed circuit board with a wired interface (wire/fiber) to a computer network. The wired information may be retrieved by a central computer system to monitor the state of the electrical components and alert if a predetermined threshold is exceeded.

Today's branch circuit monitoring computer applications document the panel within the load center and must be updated once new current transformers are attached to the monitoring system and when new electrical distribution is installed. The system alarms-on current consumption and may report on power consumption from the data it receives from the branch circuit monitoring hardware. Some data systems even go on to provide sub-metering capabilities for the charge-back of consumption of an individual circuit.

Typically these systems reside solely in the console area of a facility engineering operations center to be viewed only by the building engineers responsible for operating the building and infrastructure components of a facility. That application typically documents the power circuits in a database that stores the hundreds of load centers and the connections emanating from them. They are presented in a computer application as icons or graphical elements that represent the physical load centers. Their specific purpose is to monitor current and alarm if thresholds are exceeded. In some cases they calculate power (kW, Power Factor, etc.) typically with caveats that certain configurations of homogenous sized circuit breakers must be deployed to accurately calculate the power of the attached breakers. Some systems simply estimate power with the presumption that the voltage supplied will be close enough to provide reasonable power estimates.

In typical existing systems, hardware is installed that monitors electrical parameters (e.g. Voltage, Current, kVA) and presents them to a computer application to allow for “display monitoring” in an engineering and operations console area of .a facility or to alert via some messaging system (e.g. email, pager, text . . . ). These systems include all possible forms of network communication and alert communication (e.g. email, pagers, and text) available to network connected devices and computer systems.

These typical systems present three approaches for hardware: a single Current Transformer (CT) with 2 wires connected to a remote data collection board as shown in FIG. 6a where discernment of electrical signals takes place; an array of loosely connected CTs like Christmas tree lights connected to a remote data collection board; or an array of solid core CTs attached to a printed circuit board that is connected via ribbon cable back to the data collection board as shown in FIG. 6b. The first two solutions provide a split core CT so the solution may be installed on existing circuits. The latter provides only solid core CTs.

Another system presents us with a choice of an intelligent meter (that additionally provides kW, and Power Factor, measurements and supports polyphase circuits (e.g. 3 pole 4 wire wye and 3 pole 3 wire delta) with a monitoring interface (as shown in FIG. 6c) and self-contained central processing unit that allows for connection of remote CT's. However, the user must be standing in front of this device to operate its features. This unit displays all power information to the operator as well as allows the operator to configure circuit information to provide polyphase circuit power details. This approach provides for transmission of circuit information to a software application to communicate the status of connected systems and create alarms via the network to the software application but does not allow remote management of the meter's programming via a networked software system.

Other current only monitoring systems are unable to provide power calculations (Power factor, kW, kWHr) for polyphase circuits and thus provide caveats that all circuits must be of the same type or they make assumptions and provide estimates to the consumer.

Providing power consumption information requires knowledge of the type of electrical circuit and the phases being consumed by the circuit. Four cases exist: 1 Pole, 2 Pole, 3 Pole/4 Wire Wye circuits and 3 Pole/3 Wire Delta circuits and reference to a ground wire common to each circuit is omitted. The first case is trivial; the last three require understanding of the grouping of circuits. Typically, this has been solved by proscribing that all circuits in a load center must be of the same type e.g. all 1-pole circuits or all 2-pole circuits, for example.

One last consideration is that conventional systems provide a single facility solution. It is desirable to create an enterprise solution that allows all the independent facility operators to manage their individual facility but allow each independent facility's data to roll-up to an enterprise solution. This simplifies reporting and administration and adds significant value to business and government facility operators that support multiple facilities in their portfolio or enterprise.

### BRIEF DESCRIPTION OF THE DRAWINGS

FIG. 1 is a high level block diagram of the system showing each of the major components of the hardware and software as well as how users would interface with the system.

FIG. 2 is a block diagram of an embodiment of the workflow that will support user requests and the roles that support moves adds or changes to facility electrical systems.

FIG. 2a is a block diagram of an automated embodiment of the workflow that will support user requests and the roles that support moves adds or changes to facility electrical systems.

FIG. 3 is a graphical rendering of the user interface software in a browser and this particular view shows a panel schedule with circuits defined in a load center at Poles 1,3,5; Poles 7,9; and Poles 11,13,15 as well as the total connected load of the panel at the bottom.

FIG. 3a is a graphical rendering of the user interface in a browser showing search screen options: by panel name, by rack/cab/pod and room, by condition and room.

FIG. 3b is a graphical rendering of the user interface in a browser showing a trending and milepost report of the connected and demand loads of a panel.

FIG. 4 is a graphical rendering of the user interface in a browser showing capacity information for the enterprise level as well as individual sites and buildings that can be selected for inspection of their facility capacities.

FIG. 5 is an electrical block diagram of a branch circuit capacity monitoring system necessary to discern signals from the CT or Rogowski coil arrays and process and forward that data.

FIG. 5a is a graphical rendering of an array of Rogowski coils in the open position as they would be to install on live conductors in a panel load center.

FIG. 5b shows Rogowski coils in a closed condition with an embodiment of an additional printed circuit board attached.

FIG. 5c depicts an array of non-contact sensors embedded on a plurality of printed circuit boards showing two sections 36 and 37 having an array of 1-19 poly phase programmable integrated circuit chips and at 38. The temperature sensors for each wire depicted at 39. And the termination points for mains current and voltage sensors 40, as well as the integrated circuit chips for mains sensing at 41.

FIGS. 5D and 5E depict how each integrated circuit chip is sensing a non-contact current sensor labeled 1-21 and how they would be sampled based on sample loads 1-6 in the included table. Thus showing how programmable poly-phase integrated circuit chips can sense a non-homogenous plurality of circuits.

FIG. 5F depicts a sandwich of multi-sided printed circuit boards with non-contact sensors overlapping at 10 and 20 separated by an electrical shield at 15.

FIG. 6 depicts a typical two current split core CT's and their individual leads to attach to a data collection board

FIG. 6a depicts a typical branch circuit monitoring system data collection board and two attached split core CT's.

FIG. 6b shows a typical data collection board and 4 solid core CT arrays that may be implemented in an empty load center.

FIG. 6c shows a typical an intelligent meter that may be attached to CT's split or solid and has the capability to have poly-phase circuits declared by direct entry to the meter by an operator standing in front of the meter in the field.

FIG. 7 is a depiction of a single-line or one-line drawing typically used to describe facility electrical infrastructure.

FIG. 8 is a depiction of a panel schedule report output by a spreadsheet application like Microsoft Excel.

FIG. 9 is a depiction of a two Column load center panel containing 42 breakers and the conductors for branch circuits attached to breakers within the load center panel.

FIG. 9a is a depiction FIG. 9 showing the placement of a pair of high-density branch capacity monitoring systems.

FIG. 10 is a depiction of a user circuit request in a browser containing both project information at 1 and circuit detail information at 2.

FIG. 11 is a block diagram of the hardware/software appliance that sits in the field to collect data from intelligent electrical or facility infrastructure components.

FIG. 12 provides a data base schema necessary for a user to request a circuit request within the system.

FIGS. 15 and 16 depict prior art for a one-line diagram drawn by a computer aided drafting program.

FIG. 17 is a pictorial view of a facility's electrical components and the interaction with the present invention being described in this patent. Including a high-density branch capacity monitor at 5, a hardware/software appliance at 2 to collect data from within the facility its corresponding cloud based software system at 8 and its user interface on a tablet computer at 9.

FIG. 18 shows the output of an electrical work order for the installation of circuits by an electrical installer as a result of an end user request for a circuit installation.

FIG. 19 shows a high level graphical view of a facility electrical system providing a capacity snapshot of depicted components.

FIG. 20 shows a high level graphical view of a facility electrical system providing an efficiency snapshot of depicted components.

FIG. 21 shows a high level graphical view of a facility electrical system providing a plurality of choices for UPS models and a table of electrical, capacity and financial details for each component.

FIG. 22 shows a high level graphical view of a facility electrical system and load flow for the selected components as well as a detailed table of all parent and child elements in this view.

FIG. 23 shows a high level graphical view of a facility electrical system providing a financial snapshot of the electrical system showing power costs related to the total available UPS capacity in dollars per kilowatt as well as operating costs per useable kilowatt as well as capital cost per useable kilowatt of the electrical system.

### DETAILED DESCRIPTION OF ONE OR MORE EMBODIMENTS

The electrical system and method of the disclosure overcomes the deficiencies of prior art by providing a comprehensive hardware and software solution that significantly reduces the time necessary to engineer or design, install, and manage electrical equipment and circuits as well as manage capacity, consumption and risk of over-consuming a facility electrical infrastructure; and further provide a system and method to charge for services based on monitoring a consumption metric such as kW or track a company's consumption or reduction of carbon, or report on other common industry metrics; for example in a data center we may desire to report on its performance examining metrics like PUE or DCIE. This system and method would provide benefit to the operators of each individual facility but also allows the roll-up of a facility or group of facilities or all facilities within a business or government entity into an enterprise view. The enterprise view will show the state and status of the entire group of facilities within the business or government group. The system and method will support multiple businesses or government groups disambiguating each group's data from another thereby isolating it from other system users. This will provide an economy of scale to provide solutions and data to customers at a lower cost than could typically be achieved by a single entity solution. However, for those business or government entities whose data is so critical or sensitive the solution may be implemented as a standalone solution.

The system includes a software system that provides the electrical engineer or designer the capability to design and document the complete electrical infrastructure within a facility and describe all the parent, child and sibling interfaces between corresponding components in the facility electrical distribution system from the utility transformers where power is delivered to a facility to the load that consumes the electricity at the bottom of electrical infrastructure hierarchy.

The system also has a circuit request software collaboration system that provides a web based interface so that users may request the type and number of circuits they need installed. This request includes all information necessary for an electrical engineer to act upon the request and proceed with engineering circuits into the appropriate distribution load centers within a facility.

One embodiment of the system provides an online multi-enterprise database that allows the engineer the ability to filter for the metric they must meet to engineer new circuits. Furthermore, this database will capture all the capacity metrics of the electrical system both electrical as well as physical as an output of the engineering process as well as by monitoring the signals from existing branch circuit monitoring systems or other hardware based intelligence that already exists within the electrical infrastructure. One example of such existing intelligence would be a modbus RS-485 output on a step-down transformer and distribution center commonly referred to as a PDU or CPC.

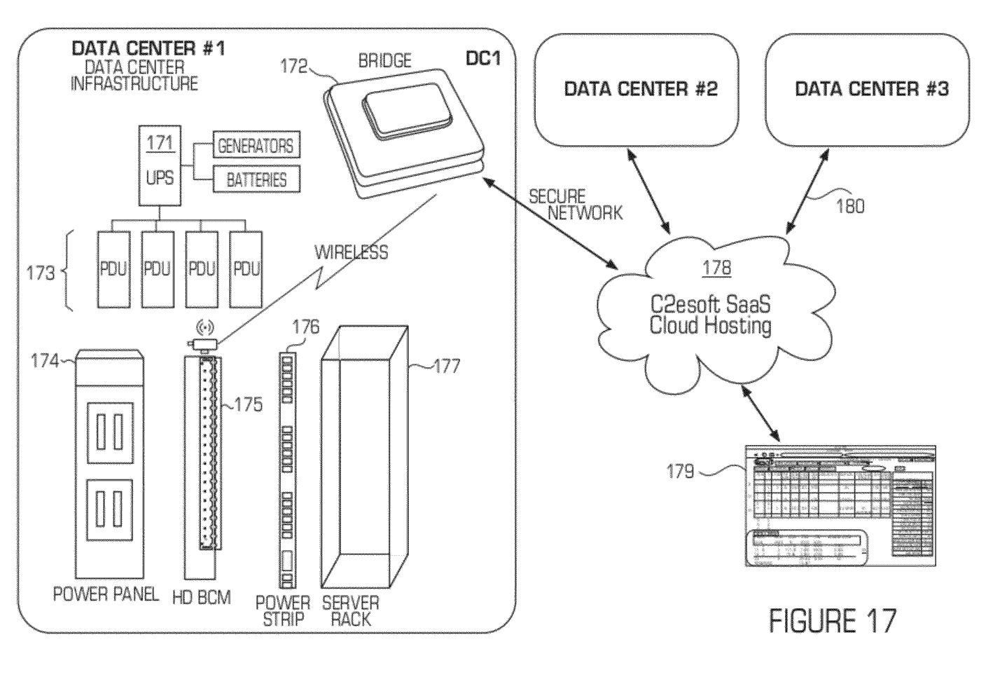

As shown in FIG. 17, the system incorporates a hardware appliance 172 that sits on the customer's site and collects information about the electrical systems being monitored. This information is stored within a database structure locally on the hardware appliance and is pushed out to the multi-enterprise database 178 to provide the user interface 179 and present status and consumption of each electrical component being monitored. This hardware appliance 172 has the capability to communicate over the LAN, its USB interface as well as to a plurality of wireless sensors communicating on an 802.15.4 wireless network. This appliance is the owner and manager of the 802.15.4 network.

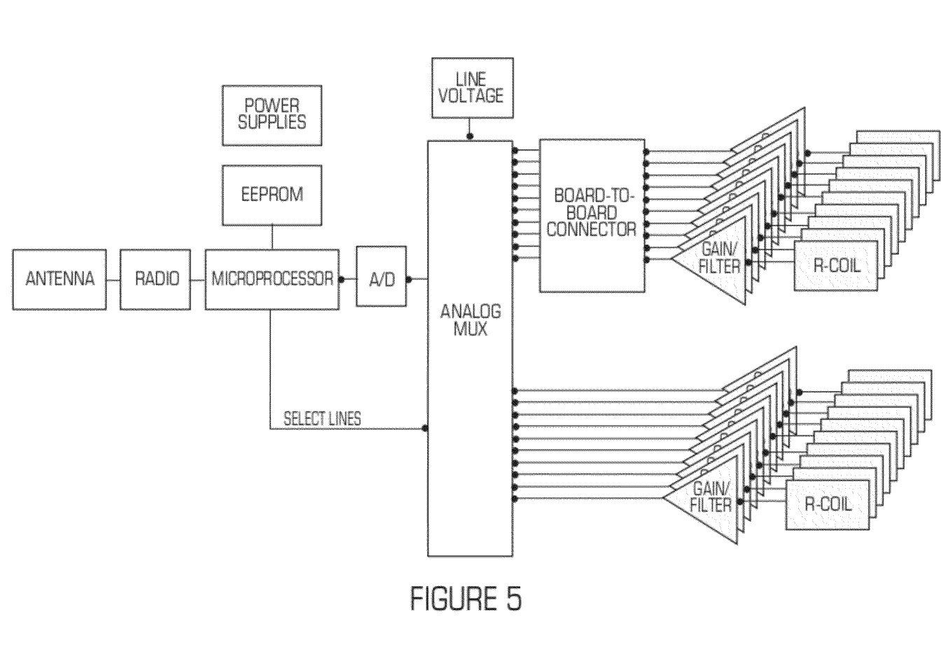

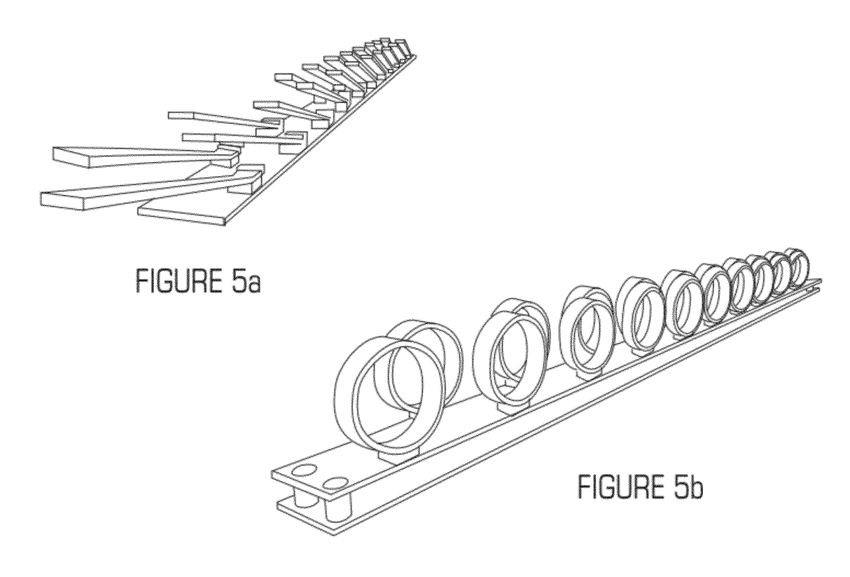

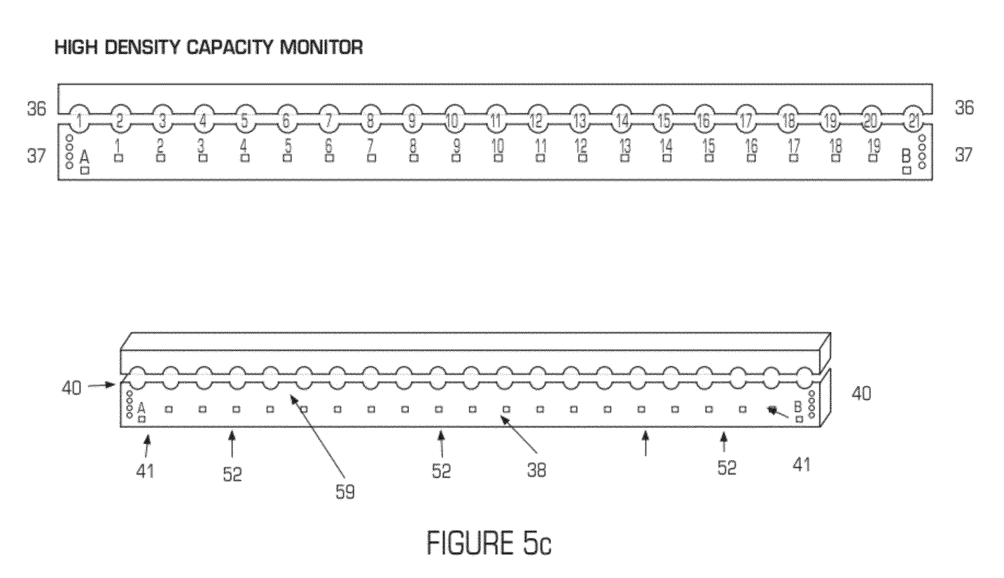

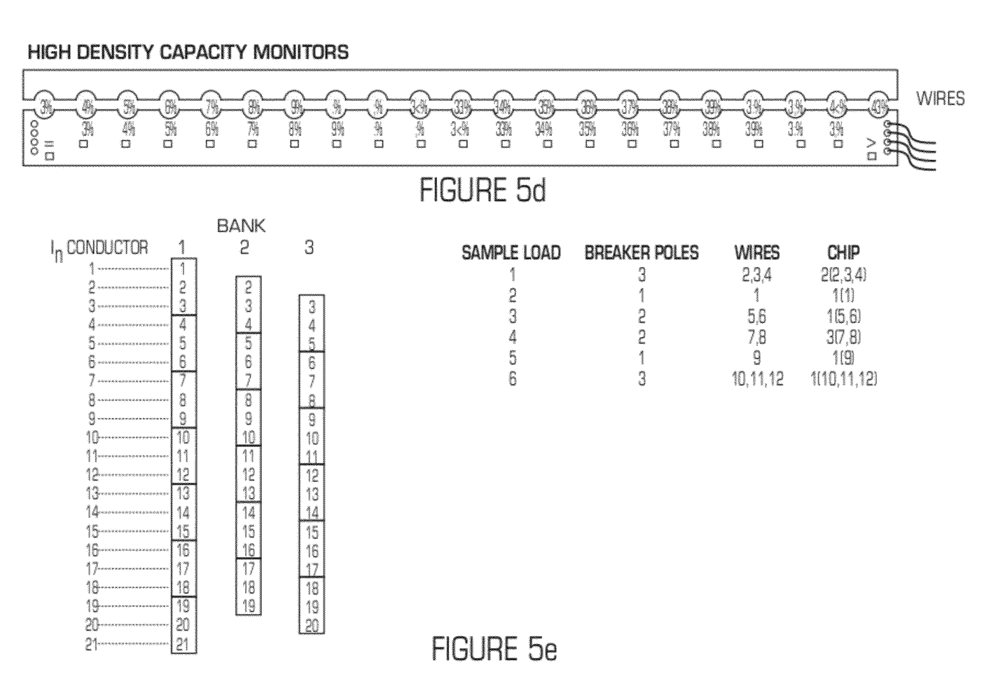

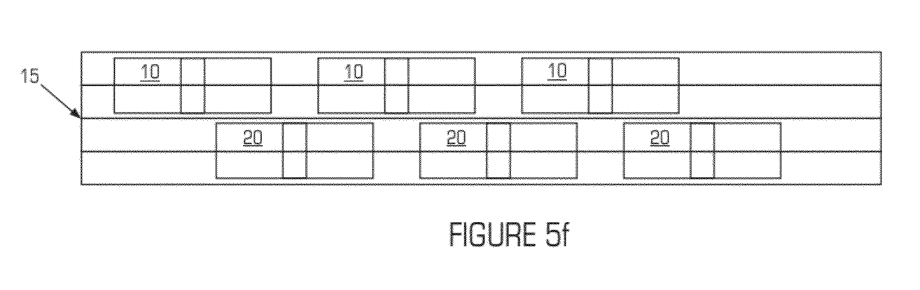

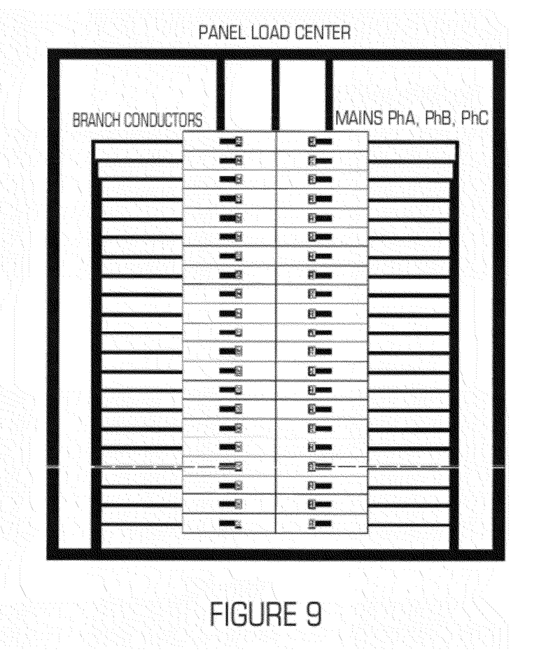

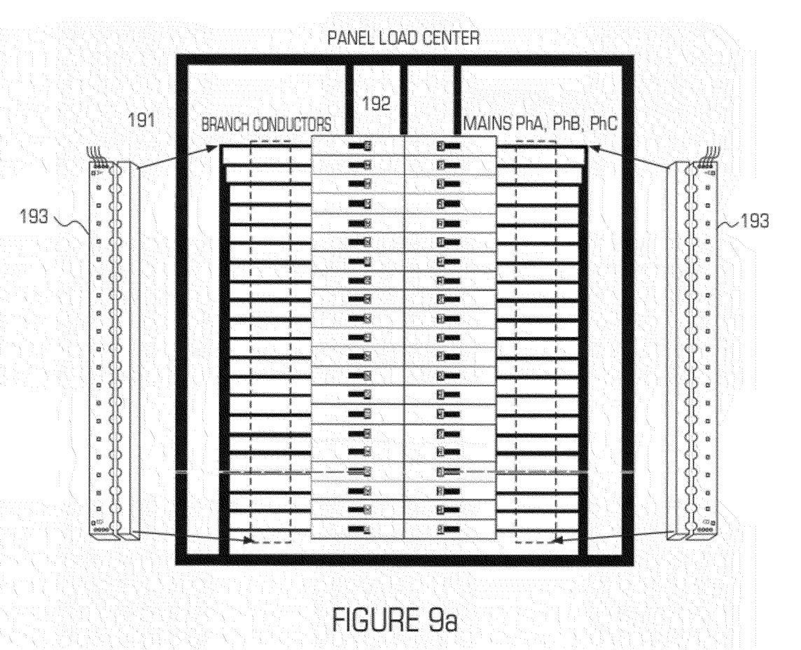

The system also provides branch circuit capacity monitoring hardware 193 (shown in FIG. 9a) that will drastically reduce the time to install such a system when installing into existing electrical distribution panels that have loads that are unable to be disconnected due to the criticality of the load receiving power out of the electrical distribution panel. This is achieved by connecting an array of split current transformers or Rogowski coils or embedded coils to a printed circuit board. This first printed circuit board will be connected to a plurality of printed circuit boards coupled to the sensor printed circuit board so that one component grouping will house an array of sensors as well as the central processing unit and signal processing components necessary to perform as a branch circuit capacity monitoring device as shown in FIG. 5. FIG. 5a, FIG. 5b and FIG. 5c. This high-density branch circuit capacity monitoring system will support multiple communication protocols, both wired and wireless. The wireless version providing the greatest advantage to the customer from a time for installation as well as cost for installation perspective.

The system and method provides a software multi-enterprise database 178 accessed from a web browser 179 via a computing device (a processing unit based device with sufficient processing power, memory and connectivity to interface with the system, such as, for example, a computer or mobile devices such as a smart phone or tablet computer) to install, engineer or design, and manage electrical equipment and circuits as well as manage capacity, consumption and latent risk of over-consuming a facility electrical infrastructure; and further provide a system and method to charge for services based on monitoring a consumption metric such as kW or track a company's consumption or reduction of carbon, or report on other common industry metrics; for example in a data center we may desire to report on its performance examining metrics like. PUE or DCIS.

One embodiment of the system includes:

A software multi-enterprise database that allows an engineer to design an electrical system, that allows a facility operator to connect it to intelligent electrical components to manage capacity; consumption and risk of the facility, that provides information necessary for the installation of a plurality of hardware such as Information Technology equipment on specific or groups of specific power circuits without over consuming the circuits or any part of the multi-pathed electrical distribution system; and providing a financial chart of accounts to track the cost of the system including power costs, capital costs and operating costs.

A software multi-enterprise database system that allows an electrical engineer or designer to describe an entire facility electrical design;

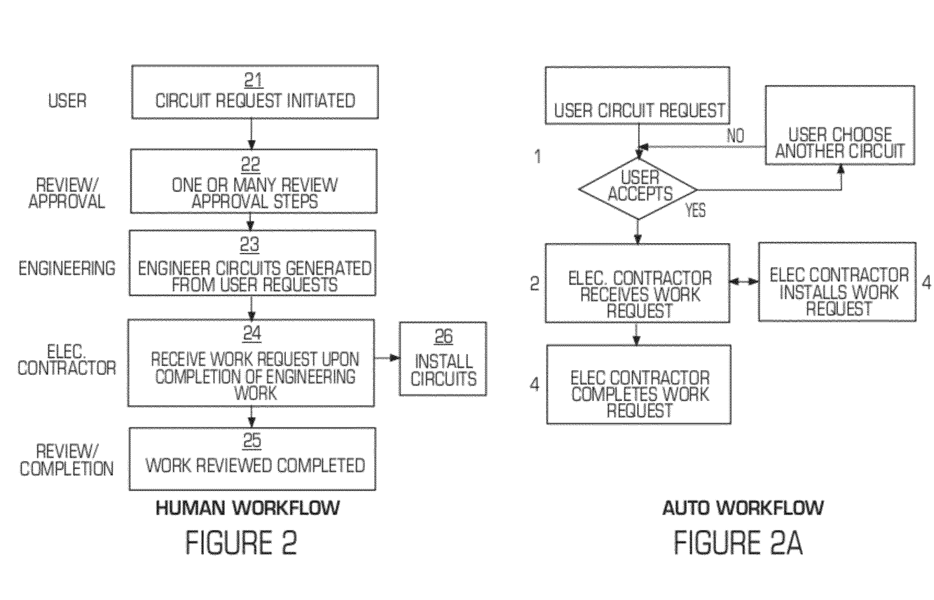

A software multi-enterprise database system that allows users to request additional electrical services within the facility as shown in FIG. 2 and FIG. 2a;

A software multi-enterprise database that tracks all consumption and capacity metrics that are described in the design of the facility and stored in the data structure;

A hardware/software appliance 172 (FIG. 17) that sits within the engineered facility and monitors, collects, stores and forwards data to the software multi-enterprise database or other customer information system via an application programming interface; and

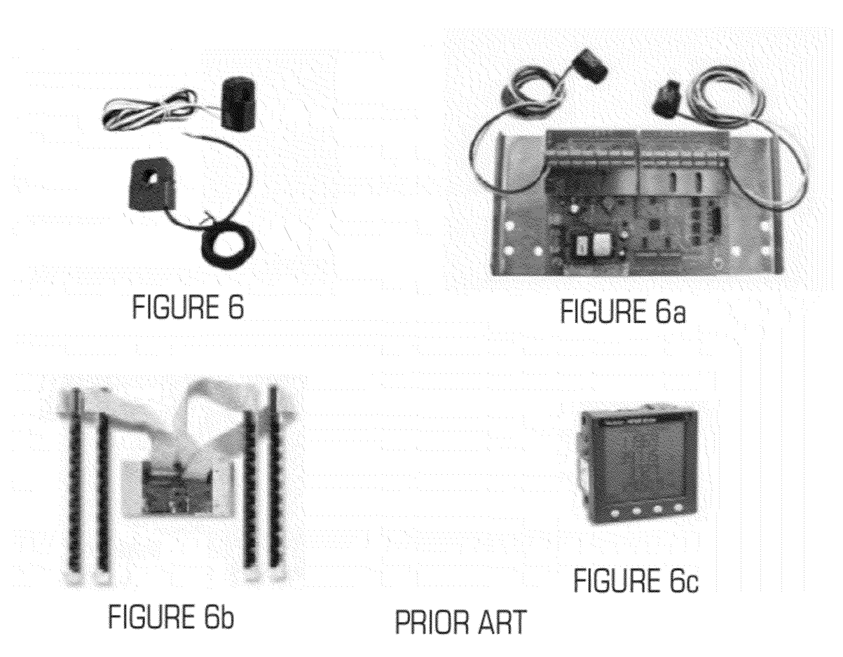

A hardware branch circuit capacity monitoring device(s) as shown in FIG. 5c that is able to be connected to an existing electrical load system that currently supports electrical distribution but is unable to be interrupted and is constructed in such a manner that it will provide dramatic savings in installation time and expense over the conventional system as shown in FIG. 6a.

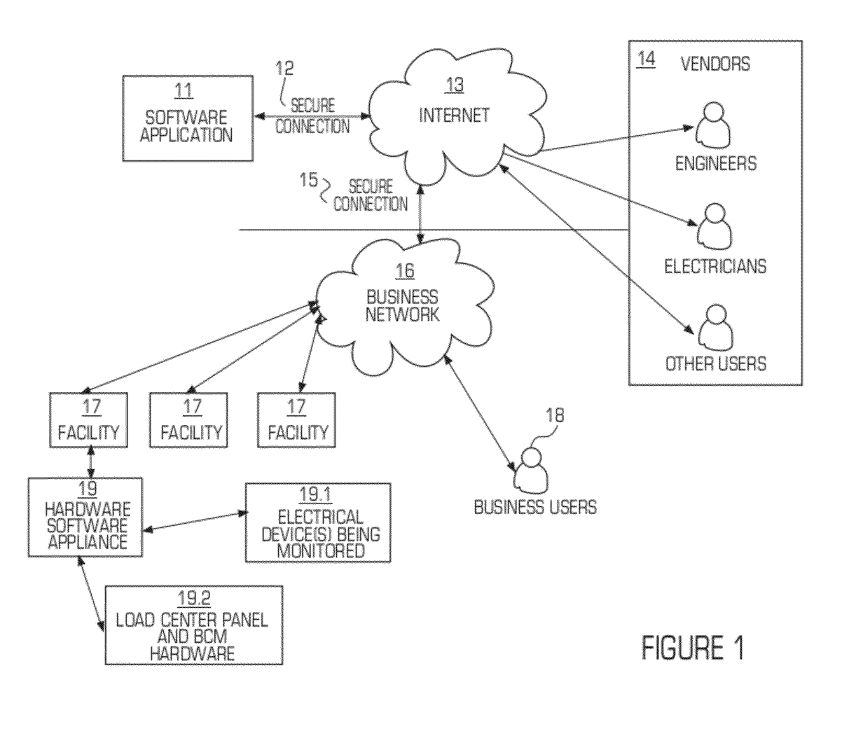

Referring to FIG. 1, a high-level overview of an embodiment of the system is illustrated. The system includes a software multi-enterprise database application 11 that allows users and vendors to communicate in the same forum. Heretofore, email has been the typical medium of communication because vendors supporting facilities rarely have access to the same network used by the owner of the facility. By providing them an off-site location to store and collaborate on data, the system increases efficiency and reduces time.

An API to a customer project management system could replace the user defined in the scenario below that could pass electrical needs to our system thus bypassing a user request step in the system.

One or more business users 18, one or more vendors 14 (such as Engineers, Electricians and other 3^{rd} party users) may access the system via secure connections from a business and Internet network 1.6 or over the Internet 13 in the case of an outside vendor. Each facility 17 may have installed a Hardware/Software Appliance 19 whose purpose is to communicate with all desired electrical components/devices 19.1 and load center branch circuit monitoring hardware 19.2 and monitor them, store that data in its local data structure and forward that data over network components 12, 13, 15, 16 to the software multi-enterprise database system 11 for analysis and presentation.

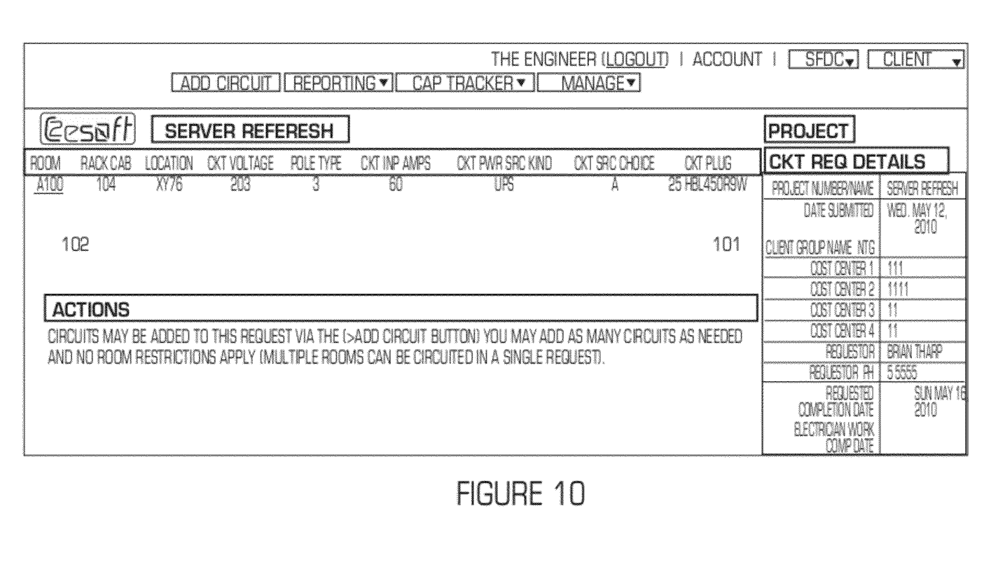

FIG. 2 illustrates an embodiment of a multi-step workflow process that may be implemented using the system shown in FIG. 1. The method begins with a user request 21 for a circuit followed by one or many review and approval steps 22 so that the user circuit request flows to a queue. FIG. 10 illustrates an embodiment of the user request where we see project data at FIG. 101 and electrical request data at FIG. 102 including the circuit size and location that it must be delivered.

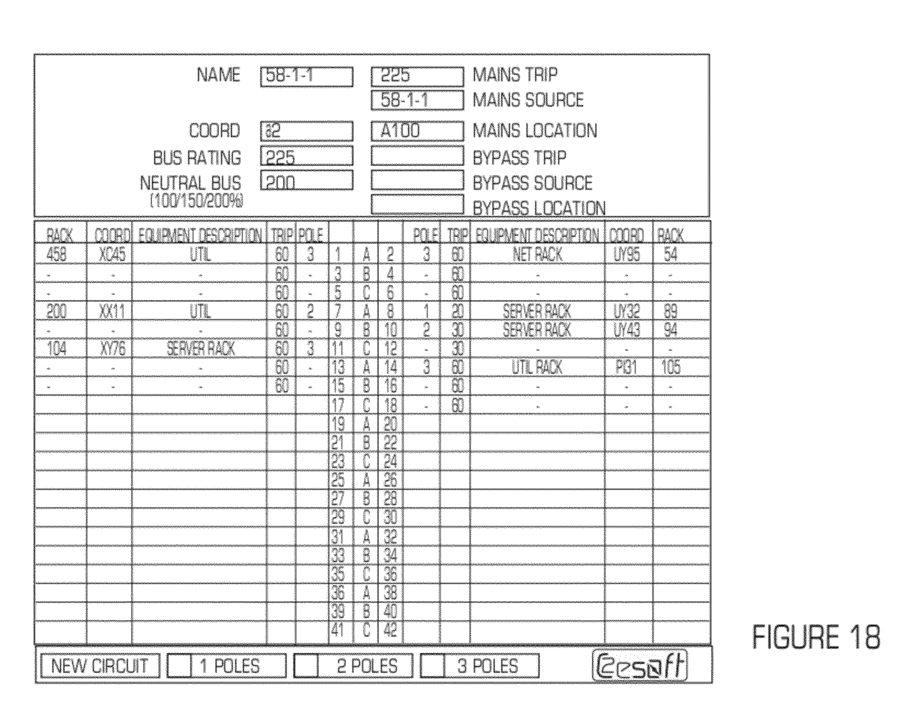

Returning to FIG. 2, an engineer or circuit designer 23 determines where to provision these circuits from and may request the system to provide the shortest route within the requested facility. Once the engineer has performed his work the request flows to a queue where an electrician or other contractor may login and examine all the work in his queue and printout work-orders 24 with all the necessary information they need to perform a circuit installation 26 which may include new panel schedules as shown in FIG. 18. This installation may also include labels necessary to physically identify and label new circuits. Finally, the implementation is reviewed and completed in the data system 25.

The review and approval flow for a business administrator 22 to keep track of project funding comes after the user has requested their circuits. This is achieved by allowing the business administrator a gatekeeper role if desired to insure that proper documentation exists for payment and scheduling. Upon their review and approval our work flows to the engineering step.

It is within the core engineering functions 23 that the system contributes significant times savings to what is in art today. In particular, no existing branch circuit monitoring systems incorporates engineering or work request processes. In our system, the engineers begin as our other users did by logging into the system and examining their work request queue. Each engineer selects their project and begins the engineering process or assigning new circuits to existing electrical distribution load centers. Before the above described system, an engineer would thumb through their paper schedules or the electronic representations in a spreadsheet program or CAD drawing and seek out a load center with the capacity necessary to fit the user circuit load criteria which is not efficient.

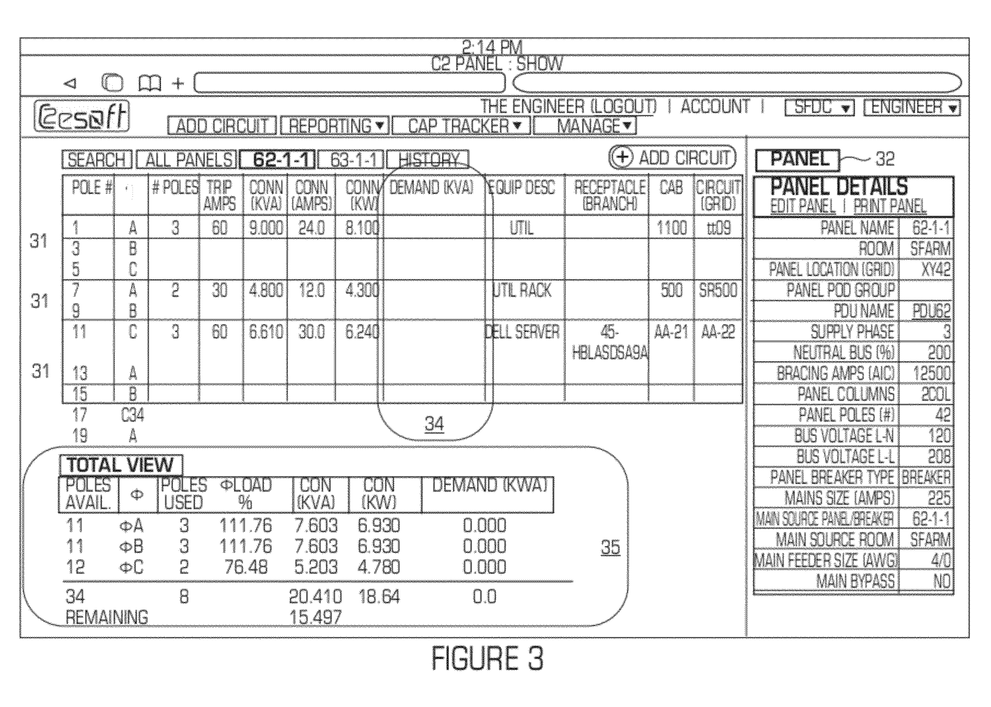

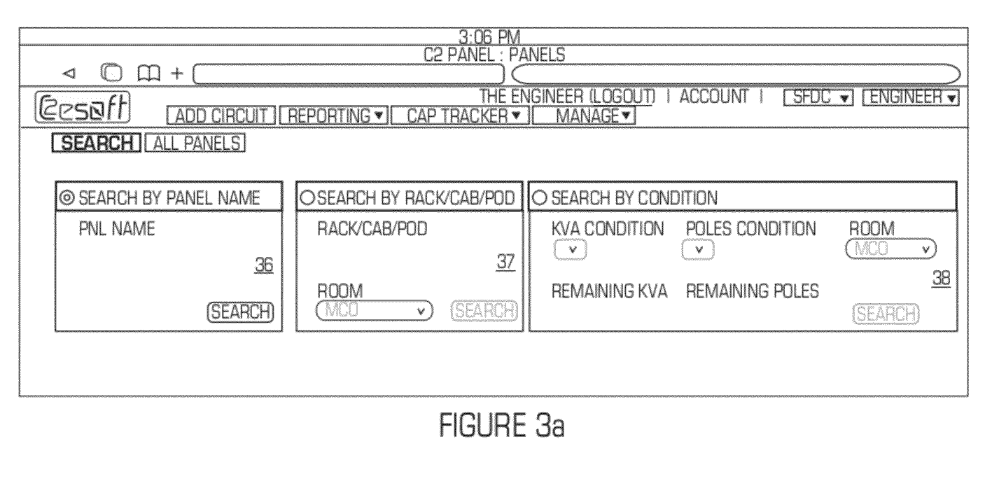

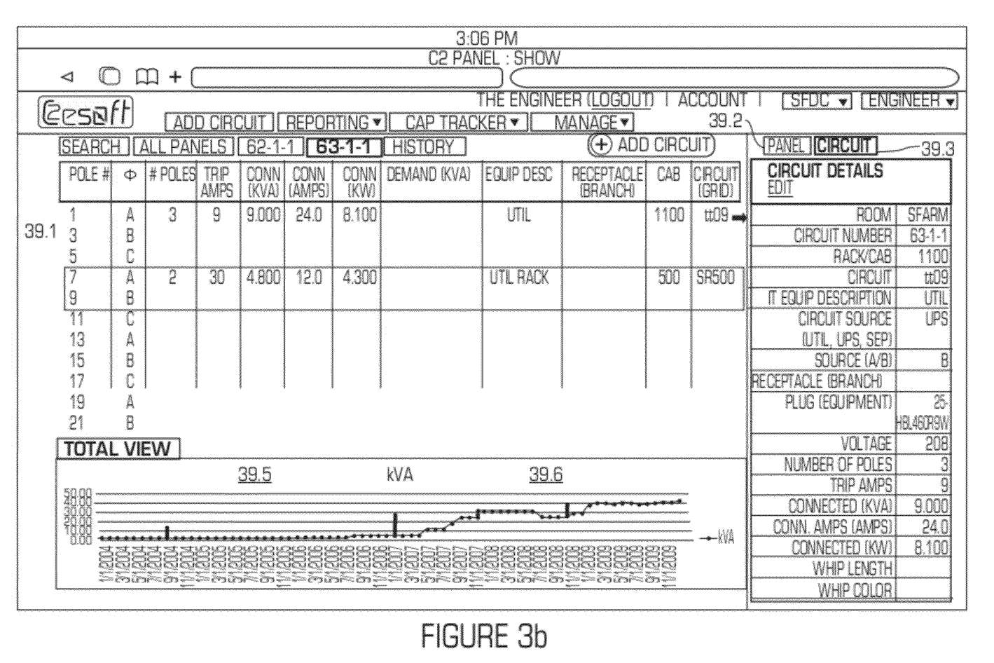

In one embodiment of the system and method, an engineer will search all the indexed panel schedules. Several possible criteria that an engineer may search (as shown in FIG. 3a at 36) would be the name or identification of an existing load center they are interested in choosing to begin their engineering examination. Another route of examination they may choose to follow would be on some physical aspect of circuits that already exist in the infrastructure such as equipment that is already being supported by a specific load center (see search by rack/cab/pod 37). Yet another choice may be to request a view of all the load centers in a specific room with a specific amount of power capacity available as well as, if desired, a specific number of breaker slots still available in the panel to outfit new circuits 38. The system provides these details in seconds saving our engineer potentially hours of work searching through static solutions documented on paper or in computer applications such as spreadsheets.

In our prior embodiment the circuit request was accomplished by having humans interface with the software system and “Engineer” or choose where to place the circuit based on the details in the user request. In another embodiment of the system we are able to automate this circuit engineering as shown in FIG. 2a by implementing capacity policies within the software system that determine how much load the electrical system may accommodate and comparing that to real-time readings that the software system obtains from the monitoring interfaces from the electrical system via our hardware appliance 172. This feature may be enabled if our users requests a circuit as before but the system will offer a solution to the user eliminating the circuit engineering step if the system has adequate monitoring coverage.

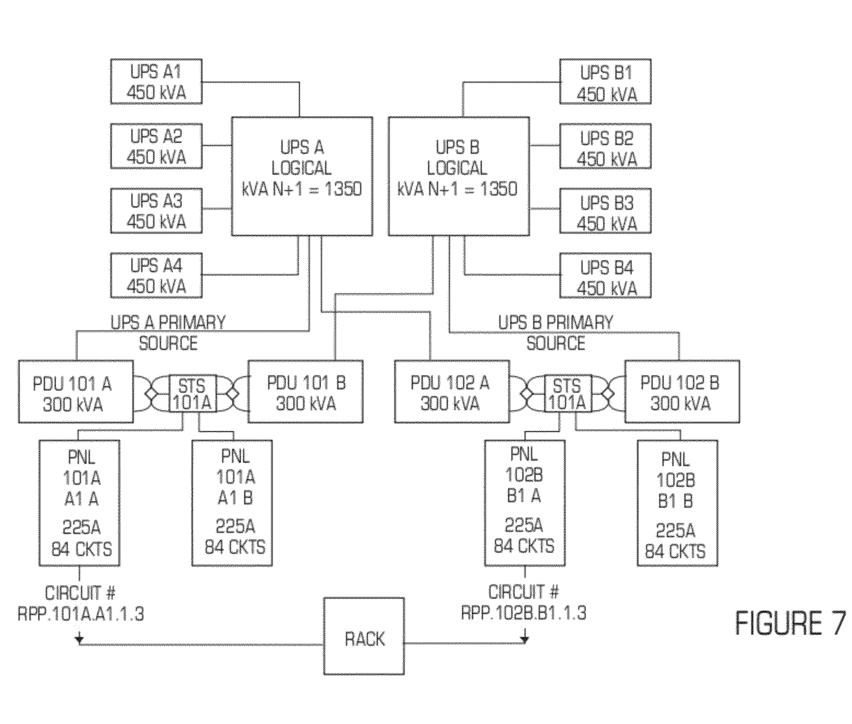

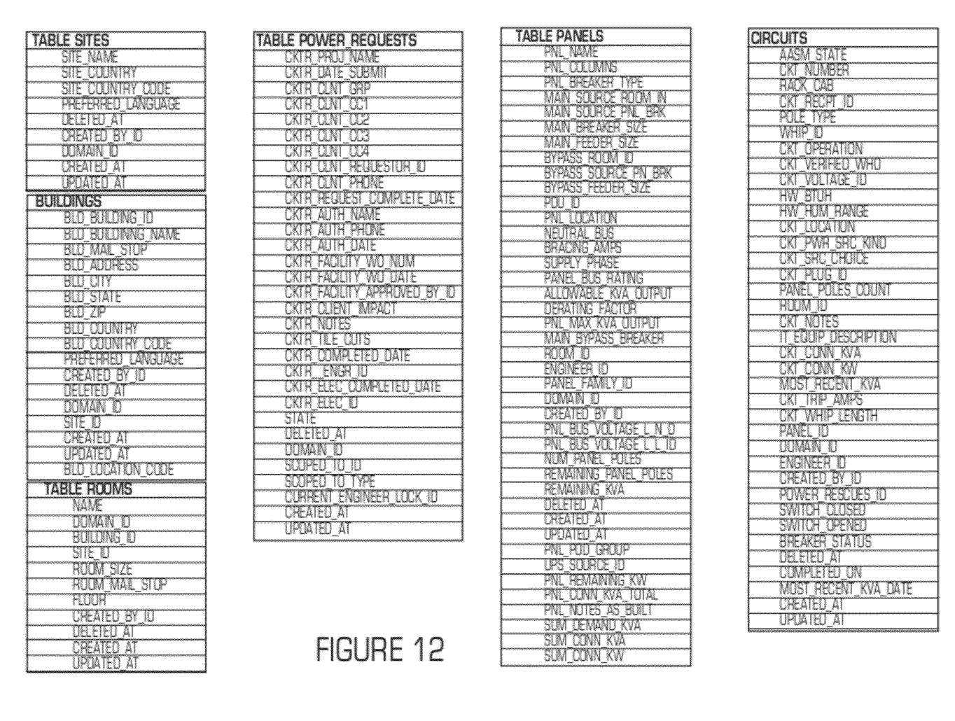

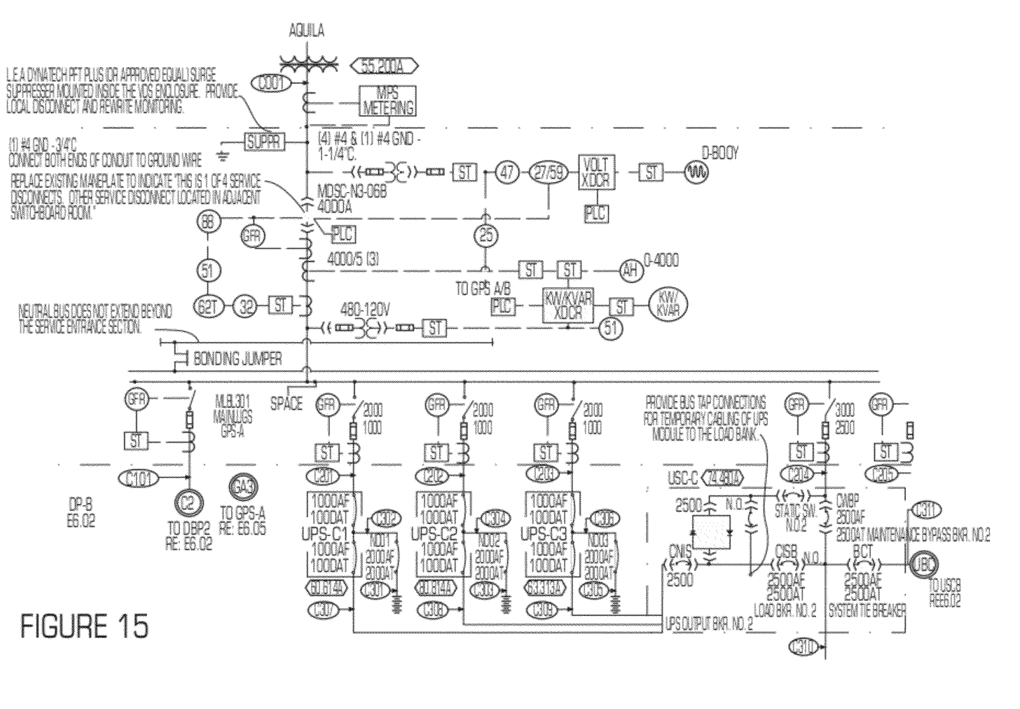

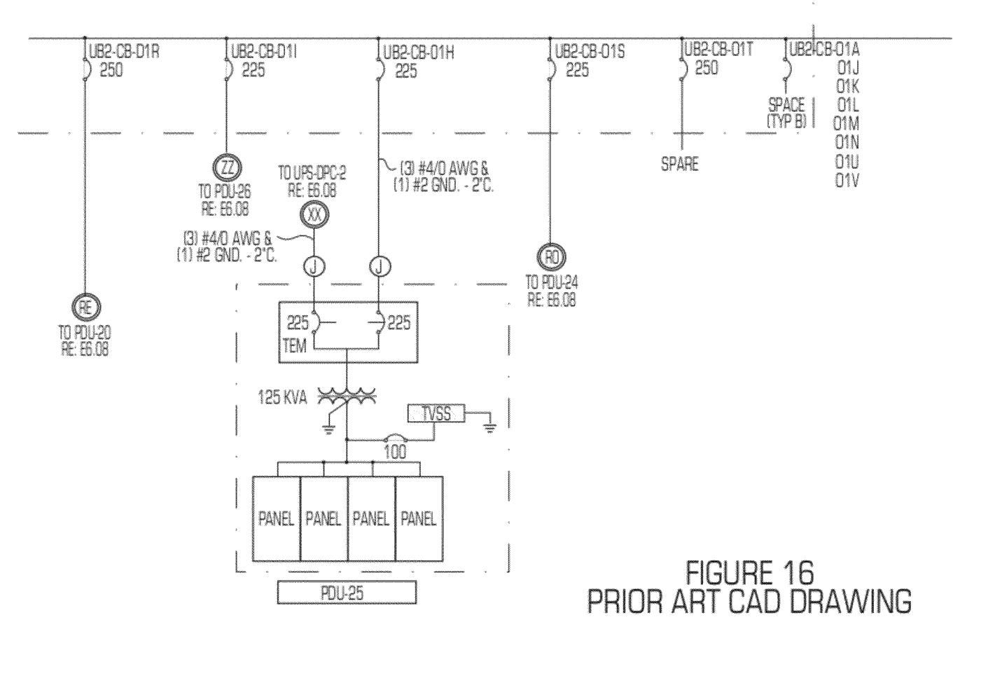

Either workflow is made possible by an embodiment of the system and method whereby the system stores all the electrical and location details of the facilities' internal electrical distribution system from the utility transformers external to the facility down to the load center panel indexes in the same multi-enterprise database system that shows the circuit request database schema FIG. 12 in use by the above workflow process. In the system, static documentation that previously existed in CAD drawings and spreadsheets are housed in a data structure that allows the indexing of the entire electrical system and all panel schedules multiple ways so that the entire electrical system and all panel schedules can be searched in various ways as shown in FIG. 3a. An output from the system may be a CAD drawing or other report based on the data relationships defined in the data structure. The system is therefore able to understand these complex relationships within the data itself and update change and delete components. All system users would have visibility to these changes, as they were committed. The system may also output information in the system into a format (CAD Drawing in FIG. 7) needed for permit submission and construction.

Facilities are not all the same but most contain many of these basic electrical infrastructure building blocks/devices that may include: Utility transformers, a utility meter, entrance electrical gear and perhaps step down transformers, automated switches that will switch the facility from one utility source to a second source if available. The facilities also may include an Uninterruptible Power System (UPS), batteries, an alternate standby emergency power source e.g. an electrical generator or flywheel system its paralleling gear to manage multiple standby sources, as well as distribution cabinets and breakers that move the electrical supply from the UPS plant to the floor where it will be consumed. Some intermediate components in the facility may include busways, distribution breakers, PDU's (a step-down transformer typically delivering 120/208V power in US based facilities) or busways and panels or RPP's (Remote Power Panels that are free standing) for distribution to the branch load (individual circuits from a panel load center) and power strips to deliver to the consumptive device.

The data system receiving data input from an engineer or designer and storing data information of the electrical hardware components in a computer data system also relates every electrical component within the building or facility to their parent, child or sibling connection and documented within the data system so that storing the work product of an engineer or other person creates updated or modified electrical system in a computer database. This data based approach would provide much more detail and be more efficient to track changes than the single line or one line drawing in a CAD system. However single lines are a typical way to communicate the logical connections between interrelated electrical components and are typically necessary to be present in a drawing or submittal package for permits or construction drawings. The data system will produce a hierarchal single line drawing as shown in FIG. 7 from its data structure to fulfill construction standards of today. Just like CAD drawing systems improved human efficiency over the drafting board and triangle the same performance improvements are imagined for a data based design approach for facility electrical systems.

The data based systems approach further provides the ability to build an enterprise record of the electrical system at a first customer's first geographic location and at a second location remote from the first location; and for a second customer with no relation to the first customer at a first geographic location and a second location remote from the first location. The data base systems approach naturally supports the transition from design to operational management of the facility it further supports input from other computer applications that may be used earlier in the Information Technology process and accept data via API's from change or project management systems.

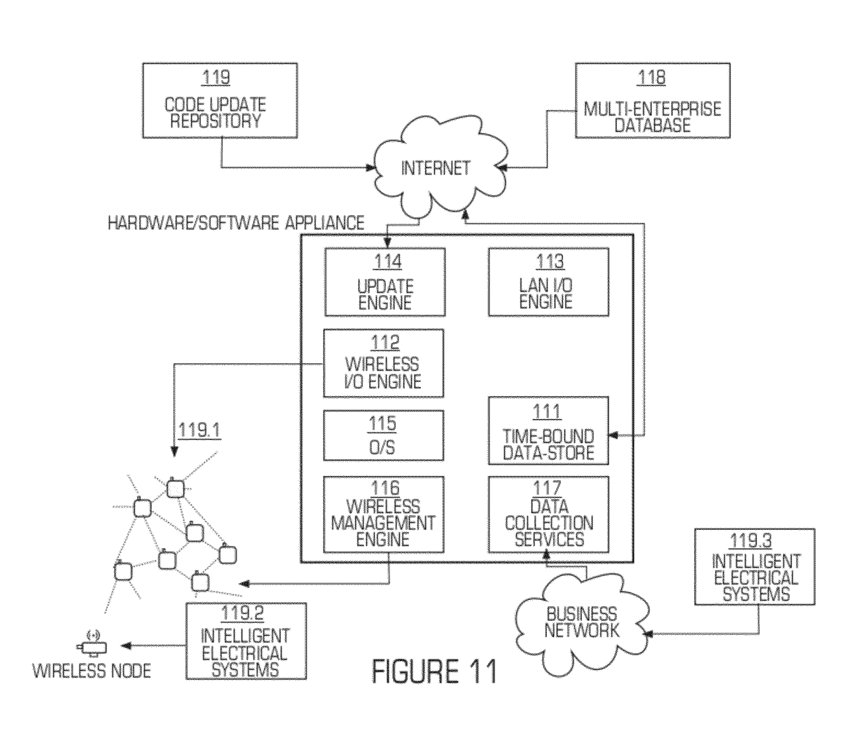

The system enables incorporation of data streams from intelligent electrical infrastructure as well as data from branch circuit monitoring systems providing demand loads 34. Demand load is defined for our purposes as the load of the system based on a measurement of the electrical load. This is possible by overlaying consumption data onto the data elements depicted by the engineer describing the facility electrical design in our data system. The real time data is achieved by using the appliance 172 within the network of the facility to monitor any desired intelligent point of the electrical distribution system. The appliance in FIG. 11 captures field data several ways. We observe that it stores time-stamped data at 111 and will move it to our multi-enterprise software system 118 as requested. Furthermore, it receives what data to collect information on from the electrical design stored in 118. Our appliance manages a wireless network 119.1 with it's wireless management engine 116 and communicates 112 with the data-store 111 from a wireless end node 119.2 that sits at an intelligent electrical device typically capable of communicating via a RS-485 protocol such as modbus. Our appliance may also communicate over its Ethernet communication port on a business LAN through its data collection services 117 to IP based intelligent devices 119.3 with protocols such as BACnet or SNMP. Finally the code and hardware firmware for the appliance is maintained via a remote code repository 119 and its internal update engine 114 that receives and updates software and firmware code to the appliance components or its wireless network nodes.

The appliance FIG. 11 is designed to sit at the customer's facility and incorporate monitoring data and collect any other intelligence from electrical, HVAC and other building infrastructure systems connected to the customers LAN, e.g. a SCADA or building management system. The appliance FIG. 11 further provides connectivity to a wireless sensor node network using a wireless protocol, such as 802.15.4 wireless mesh protocol, and manages these wireless devices. The appliance FIG. 11, when coupled with a wireless sensor node 119.1, may be used to connect to an individual unconnected electrical component to receive monitoring data or may be connected to a serial cloverleaf connecting multiple electrical infrastructure components (e.g. for a building management system) to the same serial network and collect data for each component connected to that serial network. Wireless sensor nodes may gather other environmental or information metrics and will be managed as well, for example: Temperature, pressure, humidity, RFID sensors and scanners.

The appliance FIG. 11 may communicate with the multi-enterprise database front end 118 to receive information about what the appliance is going to monitor as well push data up to the front end data structure as requested over a defined time period. For instance, the system may push data weekly per customer request and thus the system will store within the appliance's software data structure all data necessary over that weekly time interval on the local appliance. Should connectivity be disrupted the data will store locally until it has been pushed and verified by our front end.

The appliance 114 may also receive updates and code refreshes as well as additional or new capabilities by communication with a private backend code repository that is accessible by only known devices in the field. The appliance 114 will check the appliance code repository on a scheduled basis known only to the appliance and code repository systems and will not be allowed access to the code repository outside of this schedule.

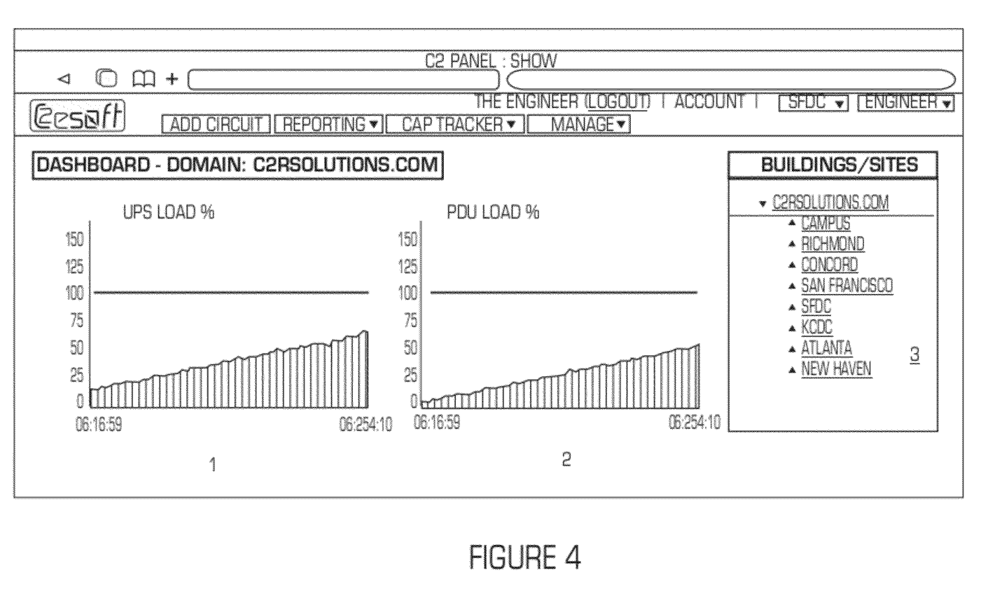

The multi-enterprise database system that couples the engineered or as built data along with the consumption data via the appliance FIG. 11 allows the system to provide the existing and remaining capacity of each component within the electrical system via the data structure and appliance FIG. 11. This capacity information aides the engineer by providing consumption data to our engineer in FIG. 3b as element 39.6 as well as providing enterprise roll-up capacity information for an entire entity (business or government) through any level of our electrical distribution system as depicted in FIG. 4 referred in the diagram as the domain. This data is invaluable to corporate facility planners and in one embodiment for IT and infrastructure systems planners to determine where to install new resources, It will also provide guidance of when and how much additional capacity may need to be constructed to keep up with demand as all implementation and consumption data is time stamped to understand consumption trends. Data will be available to understand enterprise, campus, building, floor, roam, or room segment and equipment or groups of equipment views. Enterprise is defined as all sites managed within the system for a single customer; campus is defined as a collection of buildings at a single geographic location.

The system provides current measuring mechanisms FIG. 5C that consolidate electrical signal detection and processing onto printed circuit boards and couple to a printed circuit board containing split core current transformers or Rogowski coils mounted or embedded on a printed circuit boards as shown in FIGS. 5a and 5b, 5c, thus dramatically reducing the number of components that need to be installed in a distribution load center. These sensors 21 depicted here labeled 1-21 may be mounted with the centerline spacing offered by current panel board manufactures, either ¾″ on center or 1″ on center and can be manufactured in other center patterns as necessitated by changes in panel board design. Given this sensor pattern (FIG. 5F at 10, 20) current sensors will overlap on adjacent printed circuit boards that may be sandwiched together. An intermediary shield between the adjacent sensor layers (FIG. 5F at 15) may shield the signals from the overlapping sensors (FIG. 5F at 10, 20) from one another.

The system and its new split core current transformers FIG. 5C Sections 36, 37 reduce labor internally to the load center by attaching the split CT's or Rogowski coils to a printed circuit board in an array to match the pattern of the conductors in the load center. This printed circuit board will be coupled to printed circuit board(s) that will contain the elements of FIG. 5c the data collection board needed to analyze the electrical characteristics including (current (Amps, kVA, Volts, power factor, kW, kWh, % Load, THD, Crest Factor, K-Factor) of the load center, thus creating our high-density branch circuit capacity monitoring solution. This will drastically reduce the number of components that must be installed to monitor the branch loads in a load center panel significantly reducing the labor necessary to install our branch circuit capacity monitoring solution.

One embodiment of the system provides sensing on up to 21 conductors so that 2 component pairs will support a typical 42-pole load center panel that is shown in FIG. 9a. Load center panels are typically arranged in two physical formats: a dual column as depicted in FIG. 9. having two columns of 21 breaker slots, or in a single column having 42 breaker slots. The system supports either physical configuration of the load center panel. Contacts are provided 5C.40 to analyze line voltage and terminate remote current transformers or Rogowski coils to gather load center mains breaker data as well as the neutral and ground current busses that exist within the load center panel.

We go beyond prior art that just monitors electrical signals to understand what capacity remains both electrically as well as physically e.g. how many breaker spots remain unused and available in the load center.

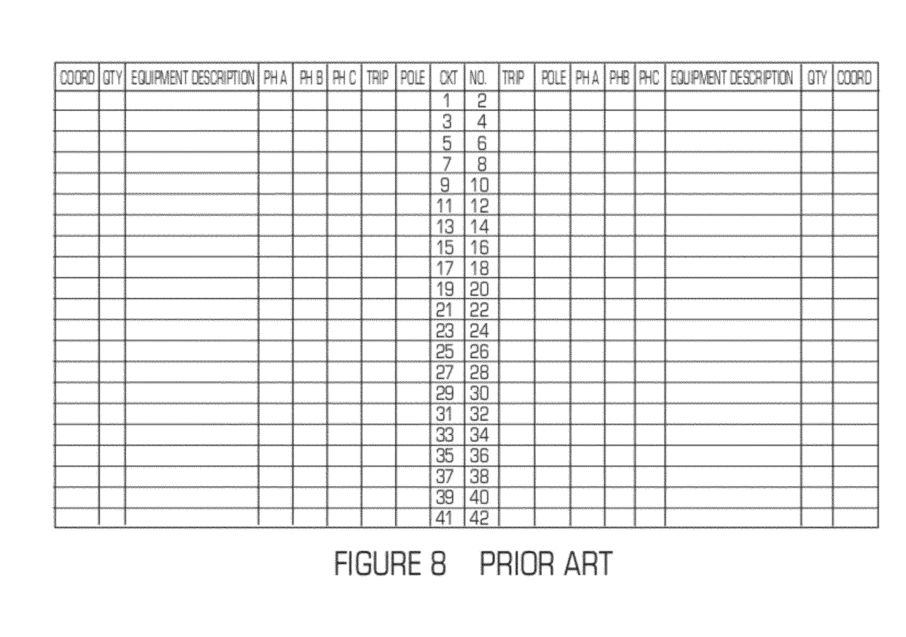

As shown in FIG. 5c, the new branch circuit capacity monitoring system eliminates the need for external wiring needed to connect to our branch circuit capacity board to a computer network by providing a wireless means of communication. This addresses labor savings external to the load center by interconnecting a plurality of branch circuit capacity monitors to a plurality of distribution load centers requiring branch circuit capacity monitoring. The branch circuit capacity monitoring solution described above may also offer standard wired interfaces either serial e.g. modbus or Ethernet LAN based e.g. BACnet. The branch circuit capacity monitor solution described above may also provide a wireless networking interface as an option available from our hardware appliance FIG. 1-9 to create a wireless mesh network 802.15.4 thus eliminating the need for pipe and wire external to the load center panel thus eliminating those installation labors costs external to the panel.

As shown in FIG. 5c, the new branch circuit capacity monitoring system eliminates the need for periodic infrared scans of electrical panels by facility maintenance personnel by incorporating a temperature sensor adjacent 59 to each conductor opening to monitor when maintenance or re-torqueing of breaker terminals must occur. This type of maintenance activity is required from time to time due the heating and cooling of the electrical conductor under load thus, causing the breaker-conductor-terminating screws to become loose causing heat build up in the wire to breaker interface due to a loosening connection from the heating and cooling. Ambient temperature conditions are sensed at 52 to understand temperature deltas between reference and wire interface.

The new branch circuit capacity monitoring system also provides for the disambiguation of tone from an electrical tracing system to trace the tone signal emanating from a toning instrument or other electrical load based system such as a power supply to confirm the source of power for that electrical load. This is very useful in a poly-supply electrical distribution system constructed to provide more than one redundant source of electrical power to assure non-disruption to electrical consuming hardware with more than one power supply. Often times systems with multiple power supplies will be misconnected resulting in all power supplies having a connection to just one leg to the multi-pathed electrical distribution system. Thus, defeating the desired objective to maintain the uptime of the load-consuming device having multiple power supplies.

The system improves on what's in the market today by communications with the multi-enterprise database engineering system that will document the placement and phases of the individual circuits before they are installed. This will allow the system to understand the power consumption of any circuit engineered anywhere within the load center shown in FIG. 9. and accurately calculate its power consumption. This is possible because we understand the makeup of the circuit within the software system as engineered by the circuit designer. It will thus eliminate the field-based setup necessary to program or install products described in existing art eliminating another field-based labor component.

Polyphase circuits within a load center have always presented a challenge to branch circuit monitoring systems because calculating the discrete power consumption (kW) of each circuit was impossible without understanding which circuit conductor was on what phase of the circuit, this was especially difficult for unbalanced three phase circuit loads. Four circuit cases exist; a 1 Pole, 2 Pole, 3 Pole Delta circuit or 3 Pole Wye circuit containing a neutral conductor. Each circuit case requires the system to understand what grouping of conductors and phase amp readings are associated with each circuit. In prior art branch circuit monitoring systems have overcome this issue by creating rules that say all circuits must be of the same case in the electrical distribution load center e.g. all 1 Pole or all 2 Pole, etc.

With this caveat they could presume the configuration of the load center and presume a unity power factor (1) and provide power data. It's rather impractical to make these presumptions in a dynamic facility, as many load centers will constantly change with the ebb and flow of new circuits over the years. Our system alleviates this issue by knowing the engineering configuration of each circuit in the electrical load distribution center and using that information to accurately calculate power from within the system where the phase of each conductor for each circuit case is known to the data structure. And then can be used to accurately select the integrated circuit chip associated with that three phase load and the integrated circuit chips associated with adjacent loads and program for that type of load on both the array and the chips FIG. 5E sample loads 1-6 and calculate the loads of a 1 Pole, 2 Pole, 3 Pole Delta circuit or 3 Pole Wye circuit containing a neutral conductor in both balanced and unbalanced cases based on circuit grouping.

The software based engineering system also manages circuit threshold monitoring as a structured part of the circuit design process thus further saving time when setting up a branch circuit monitoring system as threshold management is built into the engineering design and configuration of the electrical system. The system is able to further extend threshold monitoring by introducing capacity threshold levels and warn via (e.g. email, pager, text . . . ) as well as advising the designer to avoid the placement of any new loads on a discreet part of the electrical system during the implementation of new circuits, this may be determined by a limit at the load center or some higher component in the electrical hierarchy limiting power available in our panel load center. The system may also create other capacity limits that would create an active management system that would open a record when a discreet component exceeding its capacity was placed in this capacity queue for review and remediation by facility personnel. Finally, the system can project when new capacity is needed to be brought online by creating a build threshold that would alert our facility manager to build new infrastructure and would warn them in time to build new without depleting existing supply thus insuring no business interruption due to infrastructure scarcity.

When an electrical system has adequate monitoring at the branch distribution level as well as other critical points higher in the power supply tree hierarchy the software system may be configured to auto-provision FIG. 2a branch circuits to the end user requester of the system. This will replace intermediate human interaction with the software system to deliver new circuits. Essentially creating a shortened workflow process of just user request and circuit installation thereby making the software system the gatekeeper of all capacity information without further human intervention. The system provides a recommended circuit based on user input but allows the flexibility for the user to reject the first system suggestion and find alternate available circuit choices.

Existing paper based practice left a lot of room for waste or stranded capacity by using connected load as an engineering metric to install new branch circuits into an electrical distribution load center that supports a highly dynamic load environment. In contrast, by incorporating branch monitoring or the actual demand on a circuit along with connected load, the system provides many more facts about the environment under scrutiny and thus allows for the management of capacity within the system with less waste or stranded capacity. In particular, using the system, an engineer may further observe in FIG. 3b at a later date load placed in the past and determine if the capacity she reserved on the load center its equivalent mile posts 39.5 show the time and magnitude of a user request for new loads. The trend line 39.6 shows the actual demand load on the panel. If the engineer sees reserved load and real-time usage out of sync 39.5, 39.6 reserved load can be recalibrated by our engineer based on the actual demand. This releases stranded capacity that the engineer had booked to the load center based on the original circuit request and provides it back to the system for additional consumption.

The system may also provide metrics that may be used to charge-back consumption of facility resources based on the rate of consumption of power. Power has become one of the over-riding cost factors in today's facility. It only makes sense for business or government entities to look to this type of metric to replace past facility metrics like cost per square foot. The system thus provides a method for tracking such consumption and providing it to a business or government billing system through an Application Programming Interface (API).

The system also supports the tracking and management of all the physical appliances placed in the field to support data collection.

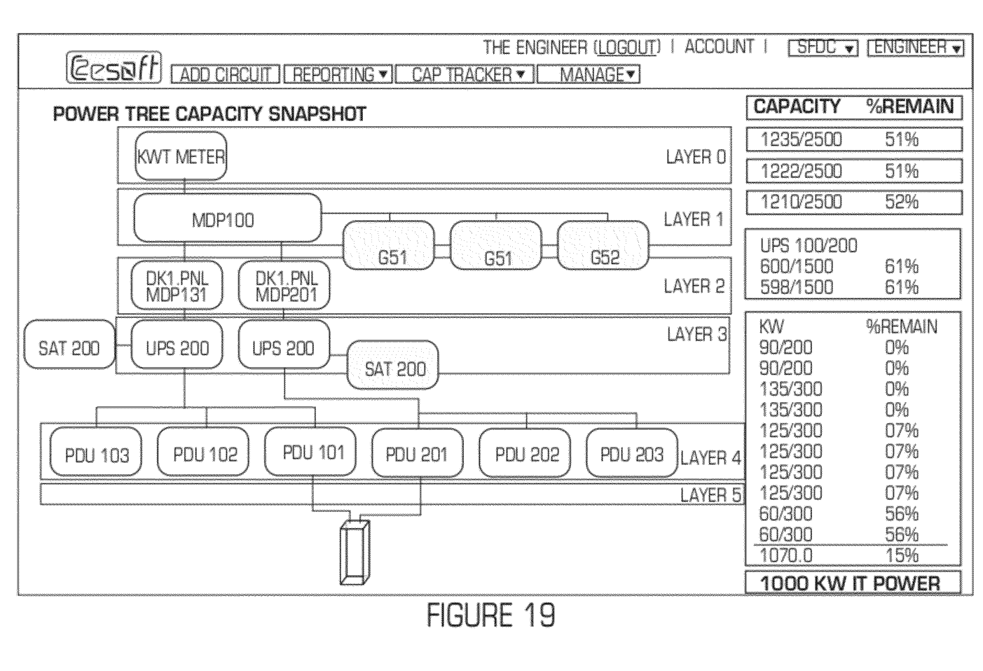

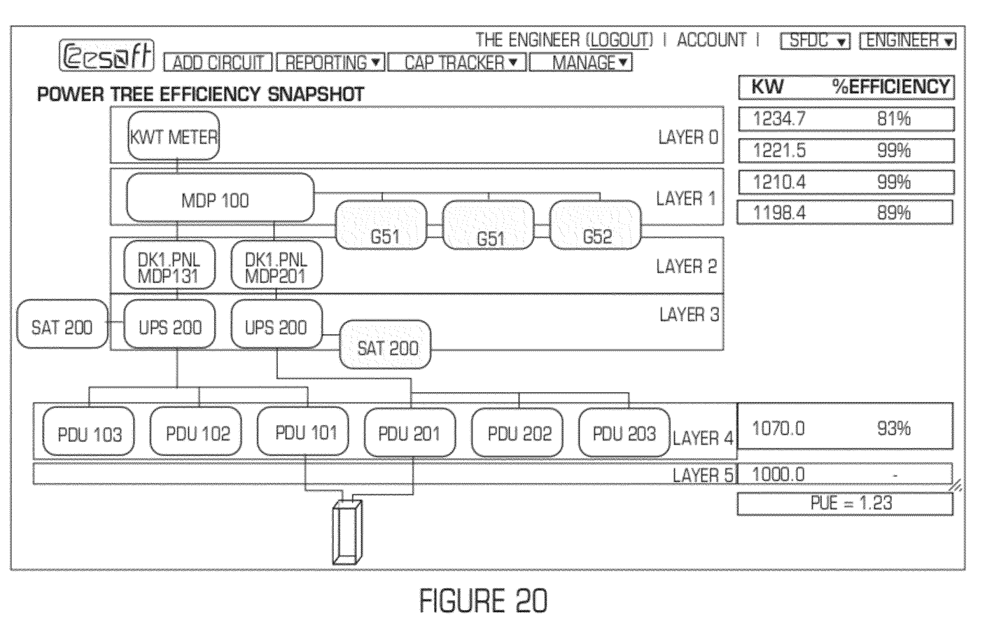

In one aspect, a system and method for engineering an electrical system, at a web browser or software application FIG. 1, for a facility electrical system FIG. 7 from its utility source or utility transformer to the electrical load or electrical consumption component are provided. The system/method receives information related to the electrical hardware components in a computer data system that relates every electrical component within the building or facility to their parent, child or sibling connection and thus documents the facility electrical system within the data system and stores the work product of an engineer or other person creating, updating or modifying the electrical system in a computer database. The system and method stores the work product of an engineer or designer for a facility or group of facilities at a first geographic location and for a facility or group of facilities at a second geographic location for a business or government entity. The system and method display the interdependencies between the parent, child and sibling electrical components FIG. 19 and FIG. 20 designed within the system in a web browser to understand the hierarchal dependencies between parent and child components, child and parent components, or sibling components within the data structure. The system and method also outputs a snap shot of the design of the electrical system in a graphical format or single-line CAD drawing format representing the hierarchal details and connections between components. Or it may provide output of various tables in CAD format necessary to provide connection documentation for the electrical system to be included in architectural plans for permit and construction purposes.

In another aspect, a system and method at a web browser for a user to request additional electrical infrastructure FIG. 2 and FIG. 2a or circuits or their addition, removal or movement are provided that involve: 1) receiving information related to the electrical components in a computer data system, or email, text or pager system thus storing the work product of the user requesting the updating or modifying the facility electrical system in a computer database; 2) forwarding that information within the users request to single or multiple approval steps and once approved by an authorized user(s) at a web browser; 3) forwarding the work product of the approval step(s) within the system to an engineer or facility designer to act on the user request to update the facility electrical system to satisfy the users request at a web browser; 4) forwarding the work product of the engineer within the systems to an electrical installer to act on the changes specified within the system by the engineer at a web browser, 5) outputting reports that depict the changes to the facility electrical system for the electrical installer to perform work and labels generated by the system to tag or physically identify the new electrical components being installed; and 6) completing the work product within the computer data system at a web browser. The request for the electrical request(s) may be displayed in a web browser or email, text or pager system to be acted upon by an approver, to be acted upon by an engineer or designer and/or to be acted upon by an electrical installer.

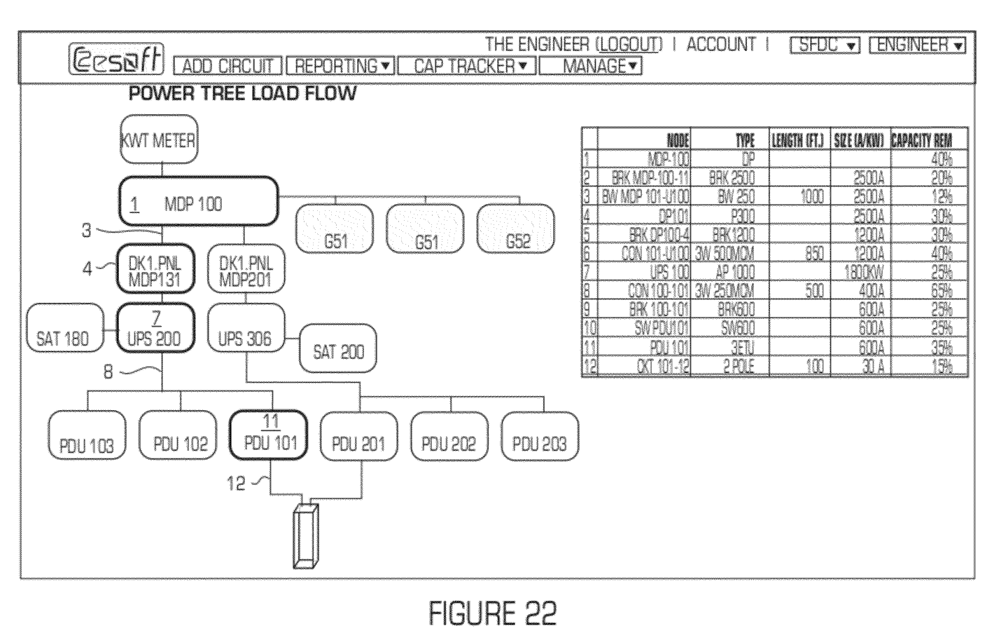

In another aspect, a system and method for electrical system capacity planning, at a web browser, a facility electrical systems from its utility source or utility transformer to the electrical load or electrical consumption component depicted in the system are provided that includes: receiving information related to the real-time characteristics of the electrical system and storing them for detailed analysis in a computer system FIG. 19, FIG. 22 or printed report the present characteristics of the electrical system compared to the beginning capacity of each component and receiving information at a web browser future loads that will be placed on the electrical system and reserving those loads against capacity of the system depicted in FIG. 1 thus providing output of the current state of the facility electrical system as well a future state of the system based on reserved loads. As shown in FIG. 17, the electrical component may be a power strip 176 connected to a power panel branch circuits or providing power to electrical consuming devices from a facility load center panel 174 or the electrical component may be a power panel, remote power panel or load center providing power to electrical consuming devices such as factory equipment, building systems infrastructure or IT hardware. The electrical component may also be a PDU 173 or electric distribution board providing the source power for the downstream components of a power panel or the output panel of a UPS 171 system or intermediary distribution board providing the source to a PDU or electric distribution board. In the system, the UPS system is documented as a single system or a plurality of aggregated systems providing conditioned and uninterruptible power to a UPS output distribution board or downstream source for a PDU. The system can be used to determine the remaining capacity of the electrical infrastructure to add additional distribution from the electrical system to load consuming devices safely and without risk of over-provisioning the system. The system creates a work or trouble queue and logs an entry to manage, build or remediate capacity issues based on a preset threshold or thresholds that may be identified in the data system work product. The system may also report on and track capacity at a single building geographic location and at a second geographic location for a building or campus or collection of buildings, and for all buildings managed by the system for the customer as an enterprise. The system may be used to support a second customer business or government entity on the same system.

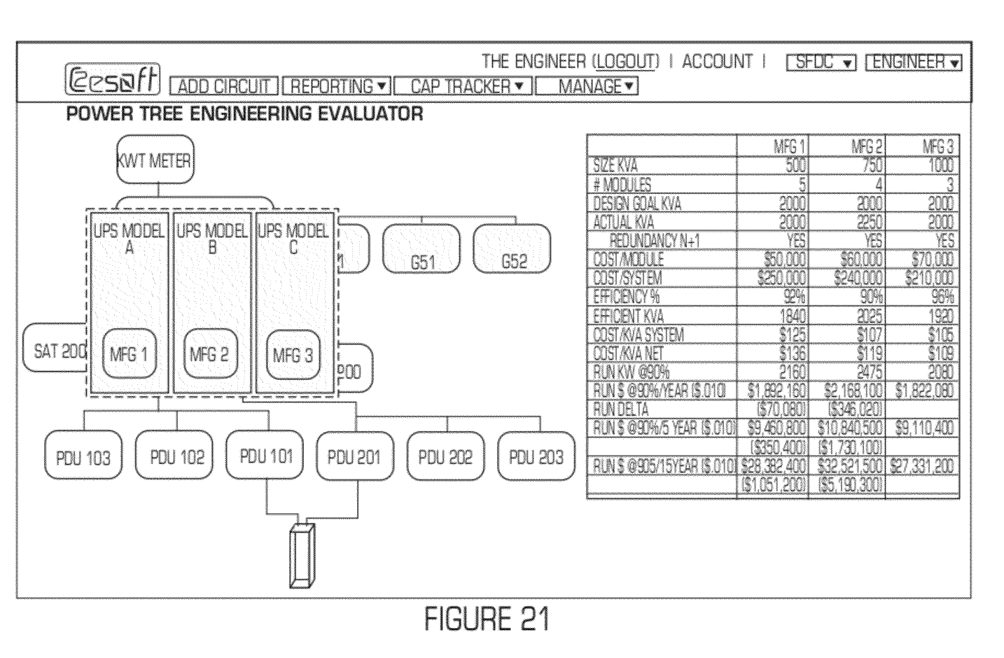

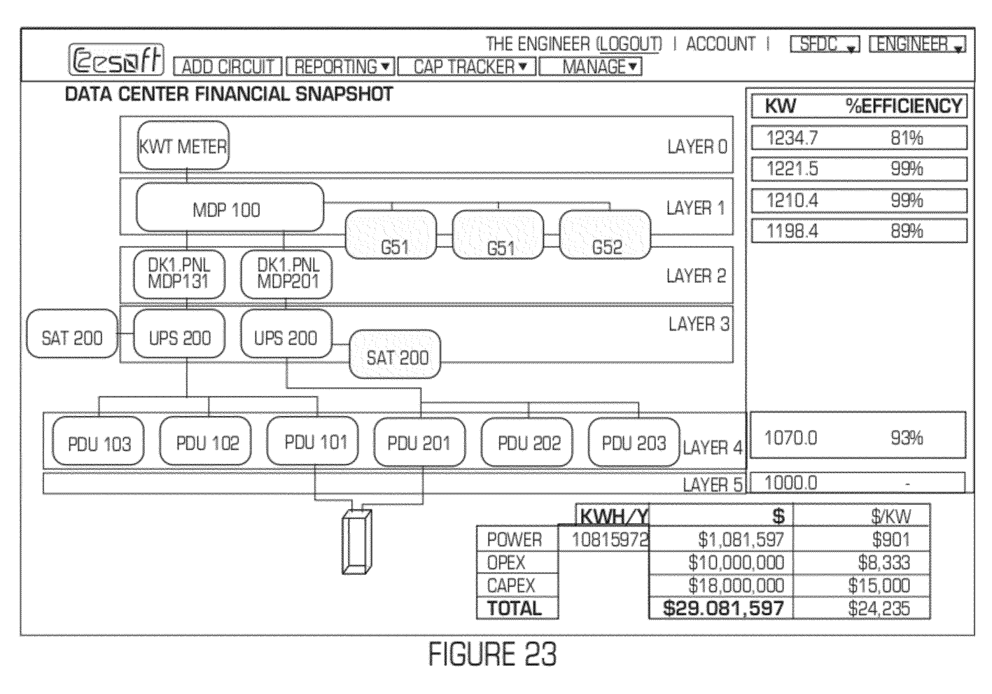

In another aspect, the system and method report FIG. 20, FIG. 21, FIG. 23, at a web browser or printed report for a facility electrical system, specialized reports about consumption and usage efficiency and organizes the data into known metrics for tracking such consumption like PUE, DCIE, Carbon Footprint, KWH, and Tons as well as others that can be constructed from within the given universe of data being tracked. The system may use the above information to improve the performance of a facility as a whole or subset of components within the electrical or cooling infrastructure of such a facility. The system also may use the above information to charge back services received from the facility infrastructure based on consumption metrics or portions thereof either to an internal corporate or governmental business entity or to an external customer of that business receiving services from that infrastructure.

In yet another aspect, a system and method to monitor and gather data of the facility electrical components on a customer's premises and storing and forwarding that data to a front-end data system from an appliance that sits on the customers internal network segment(s) and pulls data from facility electrical systems via an Ethernet connection, a serial connection or a wireless connection managed by the appliance FIG. 11 supporting multiple facility electrical communications systems protocols such as modbus and BACnet. The appliance connects to the multi-enterprise database and populates the appliance data store with all components that must be monitored. The appliance may provide data directly to another customer system directly from its own internal application programming interface or from a multi-enterprise database application programming interface and may alert on a threshold condition via email, text, pager or phone.

In yet another aspect, a system and method for monitoring power FIG. 5C in a high-density branch circuit capacity monitoring installation by consolidating split core current transformers, Rogowski coils or embedded Rogowski coils on a printed circuit board array are provided. The system may couple the printed circuit board to a circuit board containing the electronics necessary to perform circuit monitoring and interfacing with the circuit information stored in the data system with the ability to measure loads on a plurality of polyphase circuits in a distribution load center having been specifically physically constructed to reduce the time to install such a device on conductors that are unable to be disconnected. The system can be used for monitoring current and voltage of power panel mains, neutral and current ground bus bars external to the high-density printed circuit board array and for automatically associating each current sensor with its respective panel location identity thus requiring no field programming. The system can be used to monitor Current (Amps), Voltage, Reactive Power, Real Power, Apparent Power, Power Factor, Frequency, accumulated power, % Load, THD, Crest Factor, K-factor of each individual circuit and for the panel board in total requiring circuit identification from the system. The system may be used to monitor two 21-pole 193 or one 42-pole electric load center or other sizes to mate with a manufacturers panel board. The system may log electrical activity and store for later retrieval. The system may also output electrical activity data through standard building management protocols such as modbus and BACnet either through a serial connection or an IP based LAN connection or through an on-board wireless radio meeting 802.15.4 or 802.11 standards for wireless communication.

In yet another aspect, a system and method for measuring and monitoring current, KVA, KW, KWH, Power factor for polyphase circuits and calculating the discrete consumption of each circuit Fig SE as each polyphase circuits is described within the software system where the phase of each conductor that comprises the circuit FIG. 5E sample load table circuits 1-6 is known to the data structure and can be used to accurately describe each circuit to the high-density branch circuit capacity monitoring hardware. The system may be used to calculate the metrics for a single pole circuit, for a 2-pole circuit, for a 3-pole 3-wire delta circuit in a balanced or unbalanced state, for a 3-pole 4-wire wye circuit, for panel mains thus providing the load for a plurality of circuits dependent on these panel mains. The system may also determine the remaining useful capacity of a 1, 2, or 3 pole circuit and/or the remaining useful capacity of the panel mains as well as all other components measured in the facility electrical distribution system.

In yet another aspect, a system and method to calculate or auto-calculate various engineering studies of the designed electrical system such as Arc-flash, fault-current, voltage-drop, breaker coordination, conductor length ampacity studies as well as others on the entire electrical system or any two points in the electrical system as chosen by the user.

In yet another aspect, a system and method to calculate the build costs and the operations cost of the designed electrical system FIG. 21 and document multiple components at each node of the electrical hierarchal design as the engineer sees fit to compare or analyze the costs of a plurality of electrical designs from both the build and runtime cost perspectives.

In yet another aspect, a system and method to store the data associated with any component of the documented electrical system and have the ability to select that component from within the software system and reference the manufacturers or operations documentation of that component of the electrical system for reference during a maintenance or break-fix event. Furthermore, the system would be able to compare the running efficiency of the electrical system or independent components within the electrical system and compare them to the manufacturers specifications to determine if the system is running within the system-designed parameters thus discovering underperforming components that impact over-all systems efficiency and waste.

In yet another aspect, a system and method to operate each breaker, switch, auto-switch or kirk key within the software system to understand power flow within the designed electrical system just as an operator were performing the same operations on the physical power system. Out-putting each specific operation to a sequential script to provide documentation for construction or maintenance activities on the physical system.

In yet another aspect, a system and method to fail a single node or a plurality of nodes within the electrical system to determine if any load being supported by a plurality of unique electrical distribution legs will fail upon disruption, thus dropping critical electrical load through failure. This includes not only the failure of a node but also the resulting increased consumption on remaining nodes supplying power to our critical load validating if the remaining supply can maintain the load or will itself fail due to the resulting overconsumption.

In yet another aspect, a system and method to correlate financial metrics to the facility electrical system FIG. 23 by providing inspection of the cost of the facility based on a time interval such as hourly, daily, monthly, yearly and inputting the cost for power, total capital expenses and total operating expenses relating to that facility or the capability to create a chart of accounts for capital, operating and power expenses and correlating those costs to the facility. Thus providing the capability of comparing the cost of a plurality of facilities and determining differences in expenses. Several sample expenses may be the cost per kilowatt-hour based on the facility power capacity, or the cost per kilowatt hour based on the facility capital expense or operating expense.

In yet another aspect, a system and method to disambiguate the magnitude of a new load on a circuit that supports a plurality of loads, or determine the absence of a previously supported load on a circuit that supports a plurality of loads or correlating what physical hardware component has powered up or down based on the detection of load change of a circuit that supports a plurality of electrical loads.

In yet another aspect, a system and method provides for the collaboration of Engineering, Facility Operations, Information Technology and Financial teams by using the same system to provide each group visibility into the capacity, consumption, and risk to analyze the costs within the facility electrical system or the facility as a whole using power as a proxy for costs in dollars per kilowatt model instead of space, as in a dollar per square foot model. Thus predicting operating expenses over the life-cycle of the facility or potential revenue from the facility.

In yet another aspect, a system and method to analyze the need to procure wholesale power from the utility grid or go off grid to take advantage of electrical utility provider savings programs at peak times as defined by that utility operator.

While the foregoing has been with reference to a particular embodiment of the invention, it will be appreciated by those skilled in the art that changes in this embodiment may be made without departing from the principles and spirit of the disclosure, the scope of which is defined by the appended claims.

1. A method for one of engineering an electrical system and creating an as-built design of an existing facility, at a web browser or software application, a facility electrical system from its utility source or utility transformer to the electrical load or electrical consumption component, at a first customer facility and at a second customer facility geographically connected or separated from the first facility, and for a first customer not related to a second customer so that both may use common components of the system, the method comprising:
receiving information related to a set of electrical hardware components including their specifications, settings or running efficiency in a computer data system that relates every electrical component within the building or facility to their parent, child or sibling connection;
documenting the facility electrical system within the data system;
storing a work product of a person one of creating, updating and modifying the electrical system in a computer database;
incorporating one of real-time monitoring of facility sensors at various points in the physical electrical system and polling third party software systems that maintain these physical interfaces with the same points in our software system to provide facility operations the capability to monitor the facility capacity, consumption and analyze risk of the physical system;
determining if the physical facility performance correlates to the designed efficiency and performance within the software system;
providing real-time capacity, consumption and risk information to a user of the software system to determine if they may connect additional electrical loads to the system with out risk; and
providing a chart of accounts to associate financial outlays within the engineering and operations of the facility thus allowing an engineer or other user of the system to examine the substitution of electrical components within the software system to determine the best electrical system efficiency as well as capital and operational efficiency of the facility electrical system to be constructed or maintained.

2. The method of claim 1 further comprising:
providing a detailed hierarchical representation of the electrical system displaying the interconnections between all parent, child and sibling relationships that exist between the utility source and electrical load consumption components;
creating various views that retain the runtime performance of the electrical system but de-complex the detailed view into high-level views that display the performance of the system including one or more of electrical efficiency, cost of power, cost of capital expenses, cost of operating expenses; and
selecting any element depicted in the visual display and choosing to see one of meta data on that element including engineering specifics, documentation or relationships between that element and its parent, child or sibling, capacity of that element and realtime consumption of that element.

3. The method of claim 1 further comprising determining, for each component that can fail in the electrical system, an impact on the electrical system of one of: in a multi-pathed electrical distribution system fail each component that provides N+1, N+2 or N+N capacity allowing just N capacity to the load and determine if the load fails or if the N leg is over-consumed which will result in eventual failure of the N leg, failing clusters of components within the electrical distribution system that rely on a single upstream parent and determine if failure or over-consumption occurs on for one or more upstream components; and failing upstream components to understand if failure or over-consumption or other stresses occur within the electrical system.

4. The method of claim 1 further comprising:
detecting one or new and additional loads on an electrical system element that supplies power to more than one electrical load;
detecting, once recognized by the system, if an electrical load is removed from the system;
determining the magnitude and the magnitude error margin for that load;
correlating load changes with the capacity and risk analysis of the system; and
correlating that physical load to a hardware element having a network connectivity component by dovetailing load timings with other discreet events such as the appearance or disappearance of the hardware element on a wired or wireless network.

5. The method of claim 1 further comprising simulating the operations of the facility described within the software system and to manipulate every breaker, switch, or auto-switch and analyze the impact to and the load flow including magnitude within the system and choosing to output the operation of elements within the software system to a sequential script to be used in the actual performance of maintenance or construction activities on the physical electrical system.

6. A system for one of engineering an electrical system and creating an as-built design of an existing facility, at a web browser or software application, a facility electrical system from its utility source or utility transformer to the electrical load or electrical consumption component, at a first customer facility and at a second customer facility geographically connected or separated from the first facility, and for a first customer not related to a second customer so that both may use common components of the system, the system comprising:
a set of electrical hardware components at each of a first facility and a second facility;
a hardware appliance at each facility, the hardware appliance receiving information related to a set of electrical hardware components including their specifications, settings or running efficiency in a computer data system that relates every electrical component within the building or facility to their parent, child or sibling connection;
a monitoring unit, remote from the first and second facilities and linked to the first and second facilities by a link, the monitoring unit having a plurality of lines of computer code that are executed by a processing unit of a computer system that hosts the monitoring unit, the monitoring unit performing the processes of:
documenting the facility electrical system within the data system;
storing a work product of a person one of creating, updating and modifying the electrical system in a computer database;
incorporating one of real-time monitoring of facility sensors at various points in the physical electrical system and polling third party software systems that maintain these physical interfaces with the same points in our software system to provide facility operations the capability to monitor the facility capacity, consumption and analyze risk of the physical system;
determining if the physical facility performance correlates to the designed efficiency and performance within the software system;
providing real-time capacity, consumption and risk information to a user of the software system to determine if they may connect additional electrical loads to the system with out risk; and
providing a chart of accounts to associate financial outlays within the engineering and operations of the facility thus allowing an engineer or other user of the system to examine the substitution of electrical components within the software system to determine the best electrical system efficiency as well as capital and operational efficiency of the facility electrical system to be constructed or maintained.

7. The system of claim 6, wherein the monitoring unit further comprise providing a detailed hierarchical representation of the electrical system displaying the interconnections between all parent, child and sibling relationships that exist between the utility source and electrical load consumption components; creating various views that retain the runtime performance of the electrical system but de-complex the detailed view into high-level views that display the performance of the system including one or more of electrical efficiency, cost of power, cost of capital expenses, cost of operating expenses; and selecting any element depicted in the visual display and choosing to see one of meta data on that element including engineering specifics, documentation or relationships between that element and its parent, child or sibling, capacity of that element and realtime consumption of that element.

8. The system of claim 6, wherein the monitoring unit determines, for each component that can fail in the electrical system, an impact on the electrical system of one of: in a multi-pathed electrical distribution system fail each component that provides N+1, N+2 or N+N capacity allowing just N capacity to the load and determine if the load fails or if the N leg is over-consumed which will result in eventual failure of the N leg, failing clusters of components within the electrical distribution system that rely on a single upstream parent and determine if failure or over-consumption occurs on one or more upstream components; and failing the upstream components to understand if failure or over-consumption or other stresses occur within the electrical system.

9. The system of claim 6, wherein the monitoring unit detects one or more new and additional loads on an electrical system element that supplies power to more than one electrical load, detects, once recognized by the system, if an electrical load is removed from the system, determines the magnitude and the magnitude error margin for that load, correlates load changes with the capacity and risk analysis of the system, and correlates that physical load to a hardware element having a network connectivity component by dovetailing load timings with other discreet events such as the appearance or disappearance of the hardware element on a wired or wireless network.

10. The system of claim 6, wherein the monitoring unit simulates the operations of the facility described within the software system and to manipulate every breaker, switch, or auto-switch and analyze the impact to and the load flow including magnitude within the system and chooses to output the operation of elements within the software system to a sequential script to be used in the actual performance of maintenance or construction activities on the physical electrical system.

11. The system of claim 6, wherein the monitoring unit is one of a hosted application in a cloud, a hosted application on a computer system remote from the facilities and an application at one of the first facility and the second facility.

12. A method to request additional electrical infrastructure or circuits or their addition, removal or movement at one of a web browser for a user and from an application programming interface from another computer system, the method comprising:
receiving information related to the electrical components in a computer data system and storing the work product of a user requesting one of the updating and modifying the facility electrical system in a computer database;
forwarding that information within the request of the user to one or more approval steps;
forwarding, once approved by an authorized user at the web browser, the work product of the one or more approval steps to one of an engineer and a facility designer to act on the user request to update the facility electrical system to satisfy the users request at the web browser;
forwarding the work product of the engineer within the systems to an electrical installer to act on the changes specified within the system by the engineer at the web browser;
outputting reports that depict the changes to the facility electrical system for the electrical installer to perform work and labels generated by the system to tag or physically identify the new electrical components being installed;
completing the work product within the computer data system at a web browser;
automating the processes, if adequate monitoring sensors exist, so that a user may request a circuit and is provided one by the system and given the choice to accept or request another;
outputting reports, upon completion of the user request, that depict the changes to the facility electrical system for the electrical installer to perform work and labels generated by the system to tag or physically identify the new electrical components being installed; and
completing the work product within the computer data system at a web browser and thus committing new elements to the electrical systems for physical use.

13. A method for electrical system capacity planning, in one of a computer system and at a web browser, a facility electrical systems from its utility source or utility transformer to the electrical load or electrical consumption component depicted in the system, of both the electrical capacity of the system as well as the physical capacity of the system including breaker positions and termination points or attachment lugs or receptacles, the method comprising:
receiving information related to the real-time characteristics of the electrical system from embedded sensors within the physical electrical system and storing them for detailed analysis in a software system or printed report the real-time characteristics of the electrical system compared to the beginning capacity of each component and threshold limits defined within the software and set by the user to control system consumption;
receiving information about the future state of the electrical system due to be constructed and analyzing the future loads or supply within this new electrical system and how it impacts the existing prior electrical system;
receiving information at a web browser future loads that will be placed on the electrical system and reserving those loads against the capacity of the system thus providing output of the current state of the facility electrical system as well a future state of the system based on reserved loads;
analyzing those loads within the software system to insure that no over consumption occurs with the addition of the reserved loads based on the threshold limits defined within the software and set by the user to control system consumption, thus presenting real-time consumption, capacity and risk analysis to the facility operator, engineer or other interested parties;
predicting the exhaustion of any component within the electrical system and providing warning notices in accordance with the time-frame needed to build, bring online or replenish the supply of that component based on the replenish time documented within the engineering criteria for the exhausted component.

14. A system for managing electrical and physical capacity in an electrical load center supplying load to a plurality of non-homogenous circuits having no specific pattern, the system comprising:
a multilayer printed circuit board in the electrical load center;
a split high-density array of non-contact sensors that are one of attached to and imbedded in the multilayer printed circuit board to minimize installation labor time; and
wherein the split high-density array of non-contact sensors arc manufactured to meet the center dimension offset from wire to wire of various manufacturer's load centers to disambiguate spectral electrical components; measure temperature at each wire to monitor and warn of heat build up as each wire interfaces with its respective breaker or switch and compare to ambient reference points, identify signal traces from remote signal tracing devices or specialized electrical equipment able to apply a tracing tone on a wire emanating from that load center from some point in the field and have the ability to receive poly-phase circuit information from a remote software system to specify which wires being managed should be grouped into circuit groups for measurement and calculation of one pole, two pole, or three pole three-phase circuits or four pole three-phase circuits by an embedded matrix of poly-phase integrated circuit processers before storing and forwarding back to or being queried by the software capacity management system or other compatible 3^{rd} party software system.

15. The system of claim 14, wherein the split high-density array of non-contact sensors further comprises two high density half-arrays of non-contact sensors.

16. The system of claim 14, wherein each non-contact sensors is shielded to prevent crosstalk between sensors when their center to center dimension is smaller than the diameter of two sensors laid side to side.

17. A method for managing electrical and physical capacity in an electrical load center supplying load to a plurality of non-homogenous circuits having no specific pattern, the method comprising:
installing a multilayer printed circuit board in the electrical load center, the multilayer printed circuit board having a high-density array of non-contact sensors wherein the split high-density array of non-contact sensors are manufactured to meet the center dimension offset from wire to wire of various manufacturer's load centers to disambiguate spectral electrical components;
measuring, using the high-density array of non-contact sensors, temperature at each wire to monitor and warn of heat build up as each wire interfaces with its respective breaker or switch and compare to ambient reference points;
identifying signal traces from remote signal tracing devices or specialized electrical equipment able to apply a tracing tone on a wire emanating from that load center from some point in the field; and
calculating of one pole, two pole, or three pole three-phase circuits or four pole three-phase circuits by an embedded matrix of poly-phase integrated circuit processers before storing and forwarding back to or being queried by the software capacity management system or other compatible 3^{rd} party software system.

18. The method of claim 17, wherein the split high-density array of non-contact sensors further comprises two high density half-arrays of non-contact sensors.

19. The method of claim 17 further comprising installing the multilayer printed circuit board further comprises one of attaching the high-density array of non-contact sensors to the multilayer printed circuit board and embedding the high-density array of non-contact sensors in the multilayer printed circuit board.

20. The method of claim 19 further comprising shielding each non-contact sensor embedded in the multi layer printed circuit board to prevent crosstalk between sensors when their center to center dimension is smaller than the diameter of two sensors laid side to side.

21. A method for selecting from an arrayed matrix of a plurality of poly-phase programmable integrated circuits that overlap or share signals from adjacent integrated circuits chips, the method comprising:
aligning and selecting the output signal of the integrated circuit chip that aligns with a grouping of wires emanating from a electrical load center; and
forming a circuit of one of a one pole, a two pole, a three pole three-phase circuits and a four pole three-phase circuits to support the disambiguation of and management of a plurality of non-homogenous circuits with no specific pattern emanating from an electrical load center.

22. A method to measure remote mains voltage and current for an electrical load center, the method comprising:
receiving one or more signals from one or more remote sensors in the electrical load center, wherein each sensor measures temperature at each wire to monitor and warn of heat build up as each wire interfaces with its respective breaker, switch or lug and comparing to ambient reference points; and
identifying signal traces from remote signal tracing devices or specialized electrical equipment able to apply a tracing tone on a wire emanating from that load center from some point in the field.
